(19) United States
(12) Patent Application Publication
(10) Pub. No.: US 2026/0005188 A1
(43) Pub. Date: Jan. 1, 2026

(54) SYSTEMS, DEVICES, AND METHODS FOR CONFORMING DIES TO SUBSTRATES

(71) Applicant: CANON KABUSHIKI KAISHA, Tokyo (JP)

(72) Inventors: Nilabh K. Roy, Cedar Park, TX (US); Mario Johannes Meissl, Austin, TX (US)

(21) Appl. No.: 18/758,572

(22) Filed: Jun. 28, 2024

(51) Int. Cl. H01L 23/00

(52) U.S. Cl. CPC H01L 24/80; H01L 24/74; H01L 2224/74; H01L 2224/80129; H01L 2224/8018; H01L 2224/80895; H01L 2224/80896; H01L 2924/40

(57) ABSTRACT

Some devices, systems, and methods control a plurality of actuators to move a chiplet chuck holding a chiplet toward a substrate while maintaining a set tip-tilt of the chiplet chuck; detect contact of the chiplet with the substrate based on a change of a force applied to the chiplet chuck by at least one actuator of the plurality of actuators while maintaining the set tip-tilt of the chiplet chuck; and, after detecting the contact of the chiplet with the substrate, control the plurality of actuators to move the chiplet chuck toward the substrate without maintaining the set tip-tilt of the chiplet chuck and adjusting a respective force that each actuator of the plurality of actuators applies to the chiplet chuck such that a predetermined condition is satisfied.

### BACKGROUND

Technical Field: This application generally concerns bonding chiplets to bonding substrates.

Background: The manufacture of devices (e.g., electronic devices) that include multiple components requires that these multiple components be bonded together. One method of bonding these components includes aligning a first set of electrical pads (interconnect contacts) on a first product (e.g., a chiplet) with a second set of electrical pads on a second product (e.g., a substrate) and the bonding the first product to the second product. However, unobserved tip-tilt errors between the first product and the second product can introduce significant alignment errors during bonding.

### SUMMARY

Some embodiments of a method comprise controlling a plurality of actuators to move a chiplet chuck holding a chiplet toward a substrate while maintaining a set tip-tilt of the chiplet chuck; detecting contact of the chiplet with the substrate based on a change of a force applied to the chiplet chuck by at least one actuator of the plurality of actuators while maintaining the set tip-tilt of the chiplet chuck; and, after detecting the contact of the chiplet with the substrate, controlling the plurality of actuators to move the chiplet chuck toward the substrate without maintaining the set tip-tilt of the chiplet chuck and adjusting a respective force that each actuator of the plurality of actuators applies to the chiplet chuck such that a predetermined condition is satisfied.

Some embodiments of a system comprise a frame, a chiplet chuck that is configured to hold a chiplet, a plurality of actuators that are coupled to the frame and the chiplet chuck, one or more processors, and one or more memories. The one or more processors and the one or more memories are configured to control a plurality of actuators to move the chiplet chuck toward a substrate while maintaining a set tip-tilt of the chiplet chuck; detect contact of a chiplet held by the chiplet chuck with the substrate based on a change of a force applied to the chiplet chuck by at least one actuator of the plurality of actuators while maintaining the set tip-tilt of the chiplet chuck; and, after detecting the contact of the chiplet held by the chiplet chuck with the substrate, adjust a respective force that each actuator of the plurality of actuators applies to the chiplet chuck such that a predetermined condition is satisfied and control the plurality of actuators to move the chiplet chuck toward the substrate without maintaining the set tip-tilt of the chiplet chuck.

Some embodiments of a device comprise one or more communication interfaces that are configured to communicate with a plurality of actuators and a chiplet chuck that is configured to hold a chiplet, one or more processors, and one or more memories. The one or more processors and the one or more memories are configured to control the plurality of actuators to move the chiplet chuck toward a substrate while maintaining a set tip-tilt of the chiplet chuck; detect contact of a chiplet held by the chiplet chuck with the substrate based on a change of a force applied to the chiplet chuck by at least one actuator of the plurality of actuators while maintaining the set tip-tilt of the chiplet chuck; and, after detecting the contact of the chiplet held by the chiplet chuck with the substrate, adjust a respective force that each actuator of the plurality of actuators applies to the chiplet chuck such that a predetermined condition is satisfied and control the plurality of actuators to move the chiplet chuck toward the substrate without maintaining the set tip-tilt of the chiplet chuck.

### BRIEF DESCRIPTION OF THE DRAWINGS

FIG. 1 is an illustration of an example embodiment of a bonding system that is adapted to bond a chiplet to a substrate.

FIGS. 2A and 2B illustrate an example embodiment of a bonding head.

FIG. 3A illustrates the directions of the forces that are applied to a bonding-head chiplet chuck by out-of-plane actuators and by out-of-plane guiding flexures.

FIG. 3B illustrates three contact positions on the proximal surface of a bonding-head chiplet chuck and the point of rotation of the bonding-head chiplet chuck.

FIG. 4 illustrates an example of an unobserved alignment error.

FIG. 5 illustrates an example embodiment of an operational flow for bonding a chiplet to a substrate.

FIG. 6 illustrates an example of a chiplet being brought into contact with a substrate.

FIG. 7 illustrates an example embodiment of an operational flow for bonding a chiplet to a substrate.

FIG. 8 illustrates an example embodiment of an operational flow for bonding a chiplet to a substrate.

FIG. 9 illustrates an example embodiment of an operational flow for bonding a chiplet to a substrate.

FIG. 10A illustrates an example of a chiplet being brought into contact with a product substrate.

FIG. 10B shows a chiplet that is in full contact with a product substrate.

FIG. 11A illustrates an example of a chiplet being brought into contact with a product substrate.

FIG. 11B shows a chiplet that is in full contact with a product substrate.

FIG. 12 illustrates an example embodiment of an operational flow for bonding a chiplet to a substrate.

FIG. 13 illustrates an example embodiment of an operational flow for bonding a chiplet to a substrate.

FIG. 14 illustrates the x-axis, y-axis, z-axis, θ, ψ, and φ directions of a bonding-head chuck holder.

FIG. 15 is a schematic illustration of an example embodiment of a control device.

### DESCRIPTION

The following paragraphs describe certain explanatory embodiments. Other embodiments may include alternatives, equivalents, and modifications. Additionally, the explanatory embodiments may include several novel features, and a particular feature may not be essential to some embodiments of the devices, systems, and methods that are described herein. Furthermore, some embodiments include features from two or more of the following explanatory embodiments. Thus, features from various embodiments may be combined and substituted as appropriate.

Also, as used herein, the conjunction “or” generally refers to an inclusive “or,” although “or” may refer to an exclusive “or” if expressly indicated or if the context indicates that the “or” must be an exclusive “or.”

Moreover, as used herein, the terms “first,” “second,” “third,” and so on, do not necessarily denote any ordinal, sequential, or priority relation and may be used to more clearly distinguish one member, operation, element, group, collection, set, region, section, etc. from another without expressing any ordinal, sequential, or priority relation. Thus, a first member, operation, element, group, collection, set, region, section, etc. discussed below could be termed a second member, operation, element, group, collection, set, region, section, etc. without departing from the teachings herein.

And in the following description and in the drawings, like reference numbers designate identical or corresponding members throughout the several views.

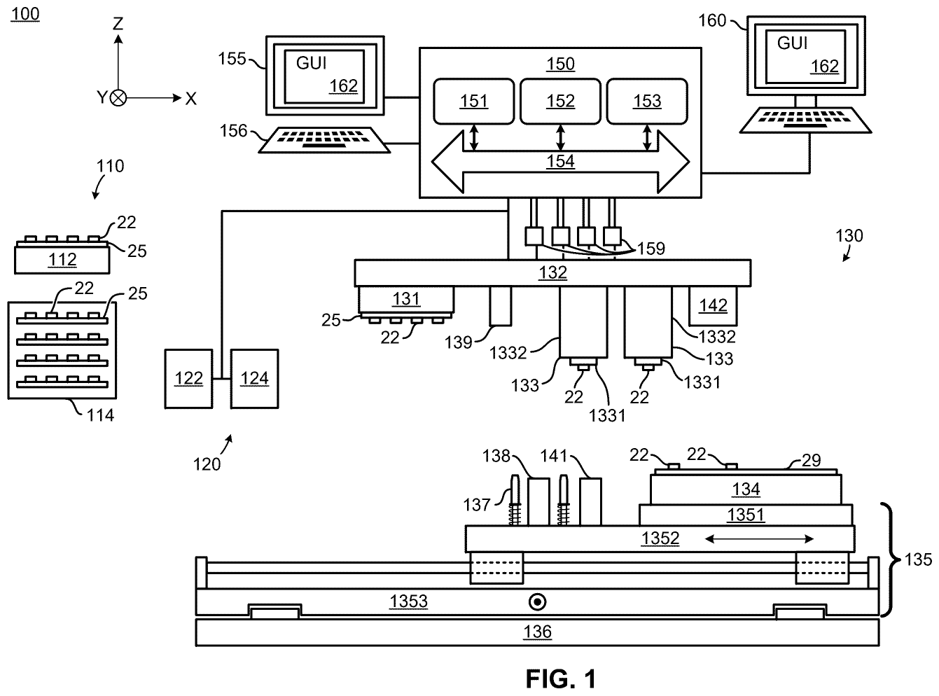

FIG. 1 is an illustration of an example embodiment of a bonding system 100 that is adapted to bond a chiplet to a substrate. As shown in FIG. 1, the bonding system 100 includes a chiplet-source section 110, a transfer-and-activation section 120, and a chiplet-bonding section 130. The chiplet-source section 110 is the portion of the overall bonding system 100 that stores or provides the source chiplets 22 that will be used in the bonding process. The transfer-and-activation section 120 activates the source chiplets 22 such that the source chiplets 22 are ready for bonding, and the transfer-and-activation section 120 transfers the source chiplets 22 from the chiplet-source section 110 to the chiplet-bonding section 130. In some embodiments, one or both of the chiplet-source section 110 and the transfer-and-activation section 120 is a respective separate apparatus. Additionally, in some embodiments, the transfer-and-activation section 120 activates the source chiplets 22 prior to the source chiplets 22 being placed in the chiplet-source section 110. The chiplet-bonding section 130 receives chiplets 22 that the transfer-and-activation section 120 supplies from the chiplet-source section 110, and then the chiplet-bonding section 130 bonds the chiplets 22 to a product substrate 29. The product substrate 29 may include chiplets 22 that are layered on top of each other. And, in the following description, the bonding of a chiplet 22 to the product substrate 29 may include the bonding of the chiplet 22 to another chiplet that was previously bonded to the product substrate 29.

As used herein, a chiplet 22 is an integrated circuit, also referred to as a microchip, a computer chip, etc. Also, a chiplet 22 is a component that includes a chiplet set of interconnect contacts. A chiplet 22 may be defined as a small block of semiconducting material on which a given functional circuit is fabricated. In the context of a substrate (e.g., wafer) that has been divided into individual chiplets 22, each chiplet 22 can be referred to as a die. A chiplet 22 will typically carry a set of integrated electronic components and circuits formed on it by patterning, coating, etching, doping, plating, singulating, etc. A chiplet 22 will typically have electrical functions, for example the following: memory, logic, field-programmable gate arrays (FPGA), accelerator circuits, application-specific integrated circuits (ASICs), security co-processors, graphics-processing units (GPUs), machine-learning circuits, specialized processors, controllers, devices, electrical circuits, arrays of passive components, etc. A chiplet 22 may also be or include a micro-electromechanical systems (MEMS) device, an optical device, an electrical-optical device, a microfluidic device, a piezoelectric device, a thermoelectric device, a spintronic device, a superconducting device, etc.

In some embodiments, a chiplet 22 has a small geometric shape (for example a rectangle or other polygon), and a chiplet 22 may have a planar dimension that is between 0.5 mm to 30 mm and may have a thickness of less than 1 mm (for example 0.8 to 0.01 mm). For example, chiplets 22 may have widths and heights on the order of 0.5 mm to 15 mm and a thickness between 10-800 μm. A chiplet 22 may have been singulated from a larger substrate, such as a semiconductor wafer, which may have been subjected to a thinning process.

The chiplet-source section 110 includes one or more sources of chiplets 22. In FIG. 1, the chiplet-source section 110 includes a source substrate 25 and a source chuck 112, which can hold the source substrate 25. A plurality of chiplets 22 are temporarily attached to the source substrate 25. In some embodiments, the source substrate 25 is a tape frame, and the source chuck 112 is adapted to mount a tape frame and help with the release of a chiplet 22 from the tape frame. In some embodiments, the source substrate 25 is a reel on which one or more chiplets 22 are mounted, and the source chuck 112 is a reel feeder. In some embodiments, the source substrate 25 is a tray with pockets for holding a chiplet 22 in each pocket, and the source chuck 112 is a tray holder. And, in some embodiments, the chiplet-source section 110 includes a front opening unified pod (“FOUP”) 114. The FOUP 114 may include a plurality of source substrates 25 and chiplets 22. Other chiplet sources known in the art may be used in the chiplet-source section 110, such as trays, adhesive tape in a frame, adhesive layer on a stiff substrate, etc.

The transfer-and-activation section 120 includes a transfer robot 122 and an activation device 124. The transfer robot 122 is able to lift and carry a substrate (e.g., a source substrate 25) to a second substrate chuck 131 in the chiplet-bonding section 130. As understood in the art, the transfer robot 122 generally includes a hand and a robot arm that provide the degrees of motion to lift, carry, and place a substrate from one location to another, such as from one substrate chuck to another or from a substrate-storage location to a substrate chuck. An example of a transfer robot 122 is commonly referred to as an equipment front end module (EFEM), which includes robots for transferring substrates of a variety of types between ultra clean storage containers, such as FOUPs. The transfer robot 122 may be any suitable device known in the art, for example robots such as the wafer handling robot RR756L15 provided by Rorze Corporation of Fukuyama-shi, Hiroshima-ken, Japan.

The activation device 124 prepares the chiplets 22 that are being transferred for hybrid bonding. Hybrid bonding is a chiplet-bonding technique in which electrically insulating (silicon dioxide) chiplet surfaces with recessed metallic pads (e.g., copper pads) are brought into contact with each other. The metallic pads are aligned with each other, while the electrically insulating surfaces are bonded to each other via direct contact. Then an annealing process is performed in which heat is applied to the bonded structure, which causes the metallic pads to expand more relative to the electrically insulating material and contact each other, thus forming electrical connections between a chiplet 22 and a product substrate 29 (e.g., between a chiplet 22 and a chiplet that was previously bonded to a product substrate 29). For example, in some embodiments, when a chiplet 22 is brought into contact with a product substrate 29, hydrogen bonds are formed between the chiplet 22 and the product substrate 29 (e.g., between the chiplet 22 and a chiplet that was previously bonded to the product substrate 29). The annealing then causes the metallic pads in the chiplet 22 and the product substrate 29 to expand and fuse into covalent bonds. In some example embodiments, the activation device 124 includes a fluid source that applies, for example, deionized water, and includes a plasma source that activates the surface of the chiplets 22 prior to the chiplets 22 being carried to the chiplet-bonding section 130 by the transfer robot 122. Due to the materials of the chiplets 22 (i.e., dielectrics), when an activated chiplet 22 is brought into contact with another chiplet 22 (which may have been bonded to a product substrate 29), a fusion bond will occur between the dielectric surfaces of the two chiplets 22.

The chiplet-bonding section 130 includes a second substrate chuck 131, a bridge 132, one or more bonding heads 133, a third substrate chuck 134 (which may also be referred to as a product chuck 134), a substrate stage 135 (which may include a rotation stage 1351, an x-motion stage 1352, a y-motion stage 1353, and possibly other stages), a base 136, one or more transfer heads 137, an upward-facing alignment system 138, a downward-facing alignment system 139, an upward-facing microscope 141, and a downward-facing microscope 142. Also, some embodiments of the chiplet-bonding section 130 include one or more shape-measurement sensors (not shown), a reference-wafer chuck (not shown), and an alignment microscope (not shown).

The second substrate chuck 131 receives source substrates 25 from the transfer robot 122. The received source substrates 25 may have chiplets 22 that have been activated by the activation device 124. The second substrate chuck 131 may be attached to the bridge 132. The second substrate chuck 131 may also be referred to herein as a transfer chuck 131.

The third substrate chuck 134 is adapted to hold a product substrate 29. The third substrate chuck 134 may be mounted to a substrate stage 135. The substrate stage 135 may provide a single axis or multiple axes (e.g., five axes, six axes) of motion control with millimeter to sub-millimeter accuracy over a limited range. The substrate stage 135 may be a highly accurate x-y-z-θ stage combined with a light interferometry measurement system so that the absolute position can be repeatedly achieved with high accuracy (for example sub-micron or better). In some embodiments, the substrate stage 135 includes a substrate rotation stage 1351, a substrate x-motion stage 1352, a substrate y-motion stage 1353, and possibly other stages.

The chiplet-bonding section 130 also includes a plurality of bonding heads 133 that are attached to the bridge 132. Each bonding head 133 can convey chiplets 22 from the one or more transfer heads 137 to a product substrate 29 that is held by the third substrate chuck 134. The bonding heads 133 may be used in parallel. And the bonding heads 133 are positioned opposite to the third substrate chuck 134. Each bonding head 133 includes a bonding-head chiplet chuck 1331, and each bonding head 133 may include a bonding-head stage 1332. The bonding-head chiplet chuck 1331 is adapted to hold a chiplet 22 in a stable, secure manner with position stability that is within, for example, 1 μm or better. The bonding-head chiplet chuck 1331 may be adapted to hold the back of a chiplet 22. In some embodiments, the bonding-head chiplet chuck 1331 is adapted to grip the edges of a chiplet 22. The bonding-head chiplet chuck 1331 may be, for example, a vacuum chuck, a latch-type chuck, an edge-gripping chuck, a pin-type chuck, a groove-type chuck, an electrostatic chuck, or an electromagnetic chuck.

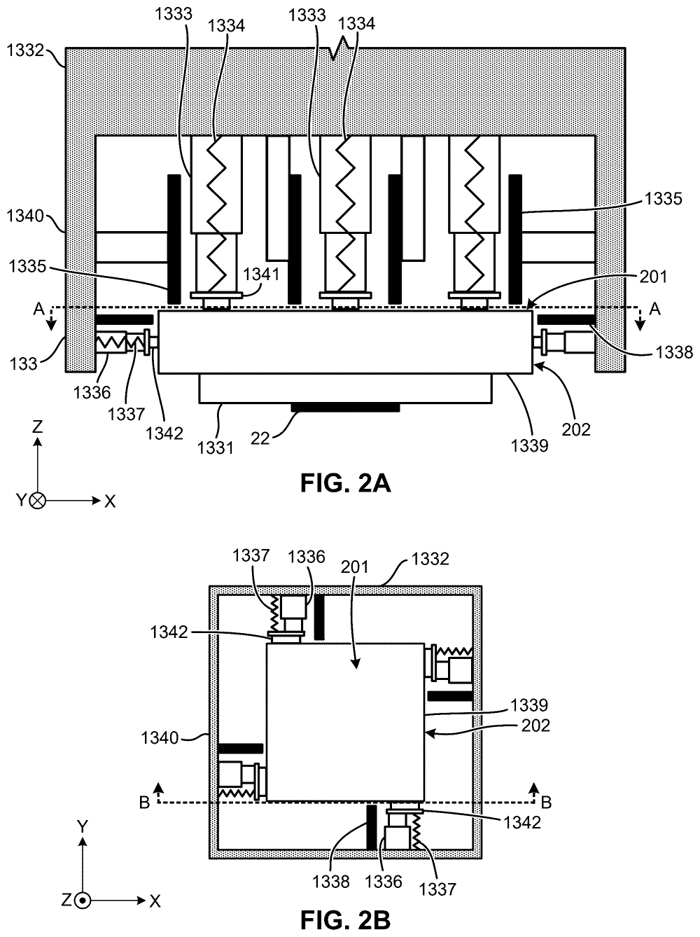

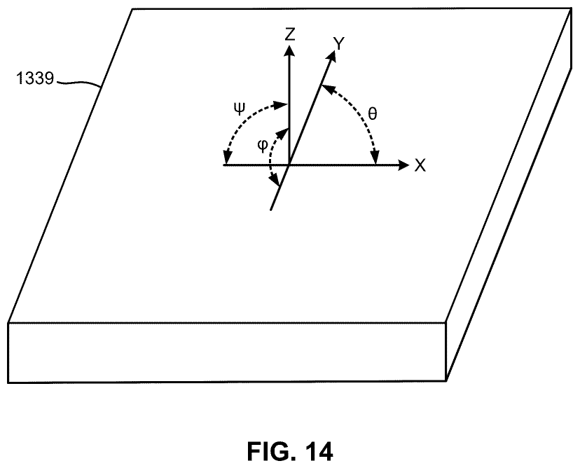

The bonding-head stage 1332 is a motion stage for controlling the position of the bonding-head chiplet chuck 1331 relative to the bridge 132. The bonding-head stage 1332 provides motion control in one or more directions, for example the z-axis direction, as well as other directions (e.g., one or more of the x-axis direction, the y-axis direction, the θ (in-plane-rotation) direction, the ψ (tip) direction, and the φ (tilt) direction, for example as shown in FIG. 14). The bonding-head stage 1332 may include one or more actuators or stages, such as voice-coil motors, piezoelectric motors, linear motors, nut-and-screw motors, piezo-actuated stages, brushless DC motor stages, and DC stepper motors. The positioning accuracy of the bonding-head stage 1332 may be within 100 nm. The bonding heads 133 are described in more detail in FIGS. 2A and 2B.

The chiplet-bonding section 130 includes one or more transfer heads 137, and the chiplet-bonding section 130 may include a plurality of transfer heads 137 that are used in parallel. A transfer head 137 is used to transfer chiplets 22 from a source substrate 25 that is held by the second substrate chuck 131 to the bonding heads 133. In some embodiments, the transfer head 137 includes a chiplet chuck that is a vacuum-type suction nozzle that can be moved in at least the direction towards the second substrate chuck 131 by one or more actuators. The tip of the suction nozzle may be smaller than the chiplet 22. In some embodiments, the transfer head 137 includes a chiplet chuck for holding the chiplet 22, for example a Bernoulli chuck, a vacuum chuck, a pin-type chuck, a groove-type chuck, an electrostatic chuck, an electromagnetic chuck, a non-contact chuck, a PEEK plastic chuck, a suction cup, an edge-gripping chuck, and the like. The transfer head 137 may include one or more actuators or stages, such as voice-coil motors, piezoelectric motors, linear motors, nut-and-screw motors, piezo-actuated stages, brushless DC motor stages, and DC motor stages stepper motors, that are configured to move the chiplet chuck to and from the source substrate 25 and the bonding head 133, for example in the z-axis direction, as well as other directions (e.g., one or more of the x-axis direction, the y-axis direction, the θ (in-plane-rotation) direction, the ψ (tip) direction, and the φ (tilt) direction).

The bonding system 100 may include or be in communication with a chiplet pretreatment system (which may include for example the activation device 124). The pretreatment that is performed by the pretreatment system may include wet and/or dry chemical processes that prepare the surface of a chiplet 22 prior to bonding the chiplet 22 to the product substrate 29. The pretreatment of the chiplet 22 may occur at any time prior to bonding the chiplet 22 to the product substrate 29. For example, the pretreatment may occur prior to the chiplet 22 being loaded onto the product substrate 29. Also for example, the pretreatment may occur while the chiplet 22 is on the source substrate 25, the pretreatment may occur while the chiplet 22 is on the transfer head 137, or the pretreatment may occur while the chiplet 22 is on the bonding head 133.

The chiplet-bonding section 130 includes an upward-facing alignment system 138. The upward-facing alignment system 138 may be used to measure the position of the chiplet 22 on the bonding head 133. The chiplet-bonding section 130 also includes a downward-facing alignment system 139 that is used to measure bonding sites 291 on the product substrate 29. In some embodiments, the upward-facing alignment system 138 and the downward-facing alignment system 139 are members of a single system that can measure both the chiplet 22 on the bonding head 133 and the bonding sites 291 on the product substrate 29.

The chiplet-bonding section 130 may include at least one upward-facing microscope 141 for inspecting chiplets 22 on the source substrate 25 that is held by the second substrate chuck 131 and also inspecting chiplets on the bonding heads 133. The bonding system 100 may include at least one downward-facing microscope 142 for inspecting the product substrate 29.

The product substrate 29 includes a substrate set of interconnect contacts, and each chiplet 22 includes a chiplet set of interconnect contacts. The substrate set of interconnect contacts may be included in a chiplet 22 that was previously bonded to the product substrate 29. The chiplet set of interconnect contacts and the substrate set of interconnect contacts will in general be referred to as interconnect contacts, which provide a plurality of connections between a chiplet 22 and a product substrate 29. In some embodiments, these plurality of interconnect contacts provide electrical connections between a chiplet 22 and the product substrate 29. In some embodiments, the plurality of interconnect contacts provide one or more of fluid connections, optical connections, or electrical connections. Each interconnect contact may be made of an electrically conductive material, such as copper. An interconnect contact may be flush with the surface of the chiplet 22 or the product substrate 29, and an interconnect contact may be dished nanometers below the surface of the chiplet 22 or the product substrate 29. The surface of the chiplet 22 or the product substrate 29 may be a dielectric material, such as silicon oxide or silicon nitride, with interconnect contacts dished nanometers below the plane of the dielectric.

In some embodiments, the product substrate 29 is a patterned semiconductor wafer that has a substrate set of interconnect contacts. The substrate set of interconnect contacts may provide connections to components within the product substrate 29 or mounted onto the product substrate 29. The product substrate 29 may have a plurality of bonding sites for a chiplet 22 and also for other chiplets different from the chiplet 22. Chiplets 22 that are identical to or different from the chiplet 22 may already be bonded to the product substrate 29. As noted above, the substrate set of interconnect contacts may be on a chiplet 22 that is bonded to the product substrate 29. In some embodiments, the product substrate 29 is not a patterned semiconductor wafer but does have a substrate set of interconnect contacts.

During the bonding process it is very important that the chiplet set of interconnect contacts and the substrate set of interconnect contacts are aligned with each other. For example, the alignment-accuracy goal may be accuracy within one or a few tens of nanometers (e.g., within 10 nm, within 20 nm, within 30 nm, within 40 nm). This becomes increasingly difficult as the size of each interconnect contact decreases and the density of the plurality of interconnect contacts increases.

The bonding system 100 also includes one or more processors 151 and one or more computer-readable storage media 152. The one or more processors 151 and the one or more computer-readable storage media 152 may be components of a control device 150. The bonding system 100 is regulated, controlled, or directed by the one or more processors 151 in communication with one or more components or subsystems of the bonding system 100, such as the source chuck 112, the transfer robot 122, the activation device 124, the second substrate chuck 131, the third substrate chuck 134, the substrate stage 135, the transfer head 137, the bonding heads 133, the upward-facing alignment system 138, the downward-facing alignment system 139, the upward-facing microscope 141, and the downward-facing microscope 142.

The one or more processors 151 are or include one or more central processing units (CPUs), such as microprocessors (e.g., a single core microprocessor, a multi-core microprocessor); one or more graphics processing units (GPUs); one or more application-specific integrated circuits (ASICs); one or more field-programmable-gate arrays (FPGAs); one or more digital signal processors (DSPs); or other electronic circuitry (e.g., other integrated circuits). Furthermore, a processor 151 may be a purpose-built controller or may be a general-purpose controller. The one or more processors 151 may include a plurality of processors that include processors that are both (i) included in the control device 150 and (ii) in communication with the bonding system 100 but not included in the control device 150. And the one or more processors 151 are an example of a processing unit.

The one or more processors 151 may operate based on computer-readable instructions in one or more programs stored on one or more computer-readable storage media 152. As used herein, a computer-readable storage medium 152 is a computer-readable medium that includes an article of manufacture, for example a magnetic disk (e.g., a floppy disk, a hard disk), an optical disc (e.g., a CD, a DVD, a Blu-ray), a magneto-optical disk, magnetic tape, and semiconductor memory (e.g., a non-volatile memory card, flash memory, a solid-state drive, SRAM, DRAM, EPROM, EEPROM). And examples of the one or more computer-readable storage media 152 include networked-attached storage (NAS) devices, intranet-connected storage devices, and internet-connected storage devices. The one or more computer-readable storage media 152, which may include both ROM and RAM, can store computer-readable data or computer-executable instructions. Furthermore, in embodiments where the one or more computer-readable storage media 152 include RAM, the one or more processors 151 can use the RAM as a work area. Additionally, when the control device 150 or the one or more processors 151 are described as obtaining information or data, recording information or data, generating information or data, storing information or data, operating on information or data, processing information or data, etc., the information or data are stored in the one or more computer-readable storage media 152. Also, the one or more computer-readable storage media 152 are an example of a storage unit. And the non-transitory computer-readable storage media 152 may be distributed among multiple processors 151.

The control device 150 also includes I/O components 153. The I/O components 153 include physical interfaces and communication components (e.g., a GPU, a network-interface controller) that enable communication (wired or wireless) with other members of the bonding system 100 (e.g., the source chuck 112, the transfer robot 122, the activation device 124, the second substrate chuck 131, the third substrate chuck 134, the substrate stage 135, the transfer head 137, the bonding heads 133, the upward-facing alignment system 138, the downward-facing alignment system 139, the upward-facing microscope 141, the downward-facing microscope 142), with other computing devices (e.g., a networked computer 160), and with input or output devices, which may include a display device 155, a network device, a keyboard 156, a mouse, a printing device, a light pen, an optical-storage device, a scanner, a microphone, a drive, a joystick, and a control pad.

Also, the hardware components of the control device 150 communicate via one or more buses 154 or other electrical connections. Examples of buses 154 include a universal serial bus (USB), an IEEE 1394 bus, a PCI bus, an Accelerated Graphics Port (AGP) bus, a Serial AT Attachment (SATA) bus, a general purpose instrument bus (GPIB), a PXI bus, a VXI bus, a VME bus, a LXI bus, and a Small Computer System Interface (SCSI) bus.

The networked computer 160 may perform analysis and may provide information, such as information concerning substrates and chiplets. In some embodiments, there are one or more graphical user interfaces (GUIs) 162 on one or both of the networked computer 160 and a display device 155 in direct communication with the control device 151 that are presented to an operator or user.

FIGS. 2A and 2B illustrate an example embodiment of a bonding head 133. The bonding head 133 includes a bonding-head chiplet chuck 1331 and a bonding-head stage 1332, which includes a bonding-head frame 1340. FIG. 2A shows a sectional view of the bonding-head frame 1340 taken from the x-z plane. FIG. 2B shows a sectional view of the bonding-head frame 1340 taken from the x-y plane. Also, the view in FIG. 2B is taken from the view indicated by line A-A in FIG. 2A, and the view in FIG. 2A is taken from the view indicated by line B-B in FIG. 2B.

The bonding-head stage 1332 also includes out-of-plane actuators 1333, out-of-plane guiding flexures 1334, out-of-plane position sensors 1335, in-plane actuators 1336, in-plane guiding flexures 1337, in-plane position sensors 1338, a bonding-head chuck holder 1339, out-of-plane decoupling flexures 1341, and in-plane decoupling flexures 1342.

The bonding-head 133 is a six degree of freedom (6DoF) bonding head. The out-of-plane actuators 1333 control the z-axis translation (the translation along the z axis), the tip, and the tilt of the bonding-head chiplet chuck 1331. The in-plane actuators 1336 control the x-axis translation (the translation along the x axis), the y-axis translation (the translation along the y axis), and the θ rotation (the rotation around the z axis) of the bonding-head chiplet chuck 1331.

In FIG. 2A, the bonding-head chiplet chuck 1331 holds a chiplet 22. And the bonding-head chiplet chuck 1331 is attached to the bonding-head chuck holder 1339.

One end of each of the out-of-plane actuators 1333 and each of the in-plane actuators 1336 is attached to the bonding-head frame 1340. Another end of each of the out-of-plane actuators 1333 is in contact with, and may be attached to, a respective out-of-plane decoupling flexure 1341. And another end of each of the in-plane actuators 1336 is in contact with, and may be attached to, a respective in-plane decoupling flexure 1342. Examples of out-of-plane actuators 1333 and in-plane actuators 1336 include voice-coil motors, piezoelectric motors, linear motors, nut-and-screw motors, and DC stepper motors.

An out-of-plane decoupling flexure 1341 decouples the respective out-of-plane actuator 1333 from the motions of the bonding-head chuck holder 1339 that are transverse to the axis of the out-of-plane actuator 1333 (the axis along which the out-of-plane actuator 1333 applies a force). Likewise, an in-plane decoupling flexure 1342 decouples the respective in-plane actuator 1336 from the motions of the bonding-head chuck holder 1339 that are transverse to the axis of the in-plane actuator 1336 (the axis along which the in-plane actuator 1336 applies a force).

An out-of-plane guiding flexure 1334 and a respective out-of-plane decoupling flexure 1341 may constitute an out-of-plane flexure unit, and an in-plane guiding flexure 1337 and a respective in-plane decoupling flexure 1342 may constitute an in-plane flexure unit.

Via the out-of-plane decoupling flexures 1341, the out-of-plane actuators 1333 can apply respective forces to the bonding-head chuck holder 1339 (and to the bonding-head chiplet chuck 1331 via the bonding-head chuck holder 1339) along the negative z-axis direction in FIGS. 2A and 2B. And the out-of-plane actuators 1333 can be controlled by the control device 150.

One end of each of the out-of-plane guiding flexures 1334 and each of the in-plane guiding flexures 1337 is attached to the bonding-head frame 1340. Another end of each of the out-of-plane guiding flexures 1334 is attached to a respective out-of-plane decoupling flexure 1341. And another end of each of the in-plane guiding flexures 1337 is attached to a respective in-plane decoupling flexure 1342. The out-of-plane decoupling flexures 1341 (and, in some embodiments, the in-plane decoupling flexures 1342) are attached to the bonding-head chuck holder 1339 such that the bonding-head chuck holder 1339 and the bonding-head chiplet chuck 1331 are suspended from the out-of-plane guiding flexures 1334 and the out-of-plane decoupling flexures 1341 (and, in some embodiments, also from the in-plane guiding flexures 1337 and the in-plane decoupling flexures 1342). Although the out-of-plane guiding flexures 1334 that are illustrated in FIGS. 2A and 2B are springs, some embodiments use other flexures (e.g., pin flexures, blade flexures, notch flexures).

Furthermore, in some embodiments, one end of each of the out-of-plane guiding flexures 1334 is attached to one end of a corresponding out-of-plane actuator 1333, one end of each of the in-plane guiding flexures 1337 is attached to one end of a corresponding in-plane actuator 1336, another end of each of the out-of-plane guiding flexures 1334 is attached to a corresponding out-of-plane decoupling flexure 1341, and another end of each of the in-plane guiding flexures 1337 is attached to a corresponding in-plane decoupling flexure 1342. Thus, an out-of-plane actuator 1333 and a corresponding out-of-plane guiding flexures 1334 may be arranged in series, and an in-plane actuator 1336 and a corresponding in-plane guiding flexure 1337 may be arranged in series.

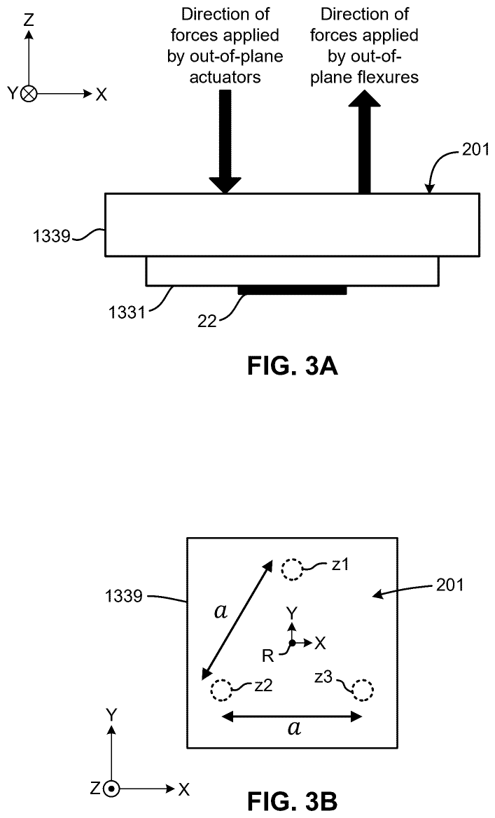

The out-of-plane guiding flexures 1334 apply respective forces to the bonding-head chuck holder 1339 (as well as to the bonding-head chiplet chuck 1331 and the chiplet 22) along the positive z-axis direction in FIGS. 2A and 2B. FIG. 3A illustrates the directions of the forces that are applied to the bonding-head chiplet chuck 1331 by the out-of-plane actuators 1333 and by the out-of-plane guiding flexures 1334. Thus, the out-of-plane guiding flexures 1334 exert forces in a direction that is opposite to the direction of the forces that are applied by the out-of-plane actuators 1333.

Via the in-plane decoupling flexures 1342, the in-plane actuators 1336 can apply respective forces to the bonding-head chuck holder 1339 in the x-y plane in FIGS. 2A and 2B. And the in-plane actuators 1336 can be controlled by the control device 150.

The in-plane decoupling flexures 1342 may be attached to the bonding-head chuck holder 1339 such that the bonding-head chuck holder 1339 is suspended, in at least in part, from the in-plane guiding flexures 1337 and the in-plane decoupling flexures 1342. Although the in-plane guiding flexures 1337 that are illustrated in FIGS. 2A and 2B are springs, some embodiments use other flexures (e.g., pin flexures, blade flexures, notch flexures). And the in-plane guiding flexures 1337 may be a different type of flexure from the out-of-plane guiding flexures 1334.

The in-plane guiding flexures 1334 apply respective forces to the bonding-head chuck holder 1339 in the x-y plane in FIGS. 2A and 2B. Each in-plane guiding flexure 1337 exerts a force in a direction that is opposite to the direction of the force that is applied by one of the in-plane actuators 1336. By controlling the in-plane actuators 1336, the control device 150 can control the θ rotation of the bonding-head chuck holder 1339 (and the bonding-head chiplet chuck 1331), which is the rotation around the z axis; the x-axis translation of the bonding-head chuck holder 1339; and the y-axis translation of the bonding-head chuck holder 1339.

In this embodiment, the out-of-plane actuators 1333 and the in-plane actuators 1336 apply respective forces to the bonding-head chuck holder 1339 through the out-of-plane decoupling flexures 1341 and the in-plane decoupling flexures 1342, which respectively connect the out-of-plane actuators 1333 and the in-plane actuators 1336 to the bonding-head chuck holder 1339. Because the decoupling flexures (the out-of-plane decoupling flexures 1341 and the in-plane decoupling flexures 1342) may be sufficiently stiff along the axes on which the actuators (the out-of-plane actuators 1333 and the in-plane actuators 1336) supply their forces, the forces supplied by the actuators are used to overcome the stiffness, and the remainder of the forces' magnitudes (any forces in excess of the forces used to overcome the stiffness) are supplied to the bonding-head chuck holder 1339. And the forces that that are applied to the bonding-head chuck holder 1339 are also applied to the bonding-head chiplet chuck 1331 via the bonding-head chuck holder 1339. Furthermore, the forces that are applied to the bonding-head chuck holder 1339 are also applied to a chiplet 22 that is held by the bonding-head chiplet chuck 1331 via the bonding-head chuck holder 1339 and the bonding-head chiplet chuck 1331. Thus, in the following description, the forces that are described as being applied to any one of the bonding-head chuck holder 1339, the bonding-head chiplet chuck 1331, and a chiplet 22 (that is held by the bonding-head chiplet chuck 1331) can be described as being applied to the others.

Additionally, because the bonding-head chuck holder 1339, the bonding-head chiplet chuck 1331, and a chiplet 22 (that is held by the bonding-head chiplet chuck 1331) move together, a movement or tip-tilt of any one of the bonding-head chuck holder 1339, the bonding-head chiplet chuck 1331, and a chiplet 22 (that is held by the bonding-head chiplet chuck 1331) can be described as a movement or tip-tilt of the others.

Accordingly, in some embodiments, a combination of flexure units (which may include out-of-plane guiding flexures 1334, in-plane guiding flexures 1337, out-of-plane decoupling flexures 1341, or in-plane decoupling flexures 1342) are arranged around a bonding-head chuck holder 1339 and enable a high-quality (e.g., nanometric) motion of the bonding-head chiplet chuck 1331 in six degrees of freedom. Each flexure unit may be a combination of a guiding flexure (an out-of-plane guiding flexure 1334, an in-plane guiding flexure 1337) in series with a decoupling flexure (an out-of-plane decoupling flexure 1341, an in-plane decoupling flexure 1342), and each actuator (out-of-plane actuator 1333, in-plane actuators 1336) is connected to the bonding-head chuck holder 1339 through a decoupling flexure. Thus, each actuator may be in parallel with a corresponding guiding flexure, and both the actuator and the guiding flexure may be in series with a corresponding decoupling flexure that is connected to the bonding-head chuck holder 1339. And each actuator and the corresponding guiding flexure may share the same ground, which is the bonding-head frame 1340 in some embodiments.

Each out-of-plane position sensor 1335 detects the distance from the out-of-plane position sensor 1335 to an area on the proximal surface 201 of the bonding-head chuck holder 1339. The control device 150 can use the out-of-plane position sensors 1335 to detect z-axis positions of areas on the bonding-head chuck holder 1339. And the control device 150 can use these z-axis positions to detect a tip-tilt of the bonding-head chiplet chuck 1331 (which has the same tip-tilt as the bonding-head chuck holder 1339), for example when the respective distances detected by the out-of-plane position sensors 1335 are not identical. Each of the out-of-plane position sensors 1335 and in-plane position sensors 1338 may be or may include the following: an interferometric position sensor; an inductive position sensor; an eddy current position sensor; a hall effect sensor; a magnetostrictive position sensor; a capacitive position sensor; a position encoder; or any other position sensor that supplies information that represents a position of an object with sub-micron or better accuracy.

The bonding system 100 also includes a plurality of electrical-property sensors 159. Each electrical-property sensor 159 may be an ammeter or a voltmeter. For example, the bonding system 100 may include a respective electrical-property sensor 159 for each actuator (out-of-plane actuator 1333, in-plane actuator 1336) in each bonding head 133. And each electrical-property sensor 159 may be an ammeter that detects the current that the control device 150 supplies to the actuator (out-of-plane actuator 1333, in-plane actuator 1336) or a voltmeter that detects the voltage that the control device 150 supplies to the actuator (out-of-plane actuator 1333, in-plane actuator 1336). The electrical-property sensors 159 supply their measurements to the control device 150. Also, in some embodiments, the electrical-property sensors 159 are included in the control device 150.

The control device 150 can control the out-of-plane actuators 1333 to adjust the tip-tilt of the bonding-head chiplet chuck 1331. For example, the control device 150 can control some of the out-of-plane actuators 1333 to apply greater forces to the bonding-head chiplet chuck 1331 than the forces that are applied by the other out-of-plane actuators 1333. Also, because the out-of-plane guiding flexures 1334 exert forces that opposes the forces that are applied by the out-of-plane actuators 1333, the forces that are applied by at least some of the out-of-plane actuators 1333 must be greater than the opposing forces that are applied by the out-of-plane guiding flexures 1334, at their current positions, to adjust the tip-tilt of the bonding-head chiplet chuck 1331 or to exert a force from the chiplet to the substrate. The tip-tilt of the bonding-head chiplet chuck 1331 will change based on the forces that are applied by the out-of-plane actuators 1333, on the contact positions on the proximal surface 201 of the bonding-head chuck holder 1339 where the forces are applied, and on the forces that are exerted by the out-of-plane guiding flexures 1334.

Also, the control device 150 can control the net moments of force (net torques) applied to the bonding-head chuck holder 1339, for example to control the tip-tilt of the bonding-head chuck holder 1339. The moments of force (force moments) are applied to the bonding-head chuck holder 1339 by the combination of the out-of-plane actuators 1333, and the moments of force may be controlled by controlling the respective moment of force that each out-of-plane actuator 1333 applies to the bonding-head chuck holder 1339. The control device 150 can calculate the respective force moments supplied by each of the out-of-plane actuators 1333 by calculating the force supplied by each out-of-plane actuator 133 in the z-axis direction multiplied by a distance between the point at which the force is applied and an axis of rotation associated with the respective force moment being calculated. A moment of force (force moment) indicates the tendency of a force to cause a body to rotate about a specific axis of rotation. The moment of force is based on the perpendicular distance from the axis of rotation to the force's vector. Accordingly, the net force moment that the combination of out-of-plane actuators 1333 applies to the bonding-head chuck holder 1339 depends on the forces that the out-of-plane actuators 1333 apply to the bonding-head chuck holder 1339, on the contact positions on the proximal surface 201 of the bonding-head chuck holder 1339 where the forces are applied, and on the axes of rotation of the bonding-head chuck holder 1339.

For example, FIG. 3B illustrates three contact positions on the proximal surface 201 of a bonding-head chuck holder 1339 and the center of rotation R of the bonding-head chuck holder 1339. In this embodiment, in the x-y plane, the axes of rotation along the x and y axes pass through the center of rotation R, which is located at the center of the bonding-head chuck holder 1339. This example embodiment has three out-of-plane actuators 1333, and thus three contact positions, positions z1, z2, and z3, through which the z-axis forces are supplied, are illustrated. Also, in the illustrated embodiment, the center of rotation R is located at the geometric center of an equilateral triangle that has vertexes at contact positions z1, z2, and z3.

For example, in some embodiments, the whole (gross) applied force Fₐₚₚ that one out-of-plane actuator 1333 applies to the bonding-head chuck holder 1339 can be described by the following:

$${F}_{app} = {F}_{elastic} + {F}_{res} , \qquad ( 1 )$$

where F_{elastic} is the force that the out-of-plane actuator 1333 applies to the bonding-head chuck holder 1339, at the set tip-tilt and z-axis position, to overcome the opposing elastic forces exerted by the flexures (which may include out-of-plane guiding flexures 1334, in-plane guiding flexures 1337, out-of-plane decoupling flexures 1341, or in-plane decoupling flexures 1342) connected to the bonding-head chuck holder 1339 to maintain the desired z-axis position and tip-tilt; and where Fᵣₑₛ is the residual force that the out-of-plane actuator 1333 applies to the bonding-head chuck holder 1339. The elastic force F_{elastic} may depend on the tip-tilt of the bonding-head chuck holder 1339 because the forces applied by the out-of-plane guiding flexures 1334 may vary depending on their respective shapes (e.g., the force applied by an out-of-plane guiding flexure 1334 may increase as the out-of-plane guiding flexure 1334 is lengthened). Thus, the control device 150 may store information that indicates the respective elastic force F_{elastic} applied by each out-of-plane actuator 1333 at multiple z-axis positions and tip-tilts of the bonding-head chuck holder 1339. And this information may indicate the respective force that each out-of-plane guiding flexure 1334 applies at multiple tip-tilts and positions of the bonding-head chuck holder 1339 in the z-axis direction relative to the resting plane. For example, the control device 150 may store a model (e.g., a table, a matrix) that indicates the forces (e.g., elastic forces) that are applied by the out-of-plane guiding flexures 1334 (and, in some embodiments, the in-plane guiding flexures 1337) over the entire motion space of the bonding-head chuck holder 1339 or that indicates the respective elastic force F_{elastic} applied by each out-of-plane actuator 1333 over the entire motion space of the bonding-head chuck holder 1339.

Thus, in some embodiments, the residual force Fᵣₑₛ can be described by the following:

$${F}_{res} = {F}_{app} - {F}_{elastic} . \qquad ( 2 )$$

In this embodiment, the total residual force F_{res_z} that the out-of-plane actuators 1333 apply to the bonding-head chuck holder 1339 (and thus to bonding-head chiplet chuck 1331) in the negative z-axis direction, the moment of force Mₓ that the out-of-plane actuators 1333 apply around the x axis, and the moment of force M_{y} that the out-of-plane actuators 1333 apply around the y axis can be described by the following:

$$[ \begin{matrix}{F}_{res \_ z} \\ {M}_{x} \\ {M}_{y}\end{matrix} ] = [ \begin{matrix}1 & 1 & 1 \\ a / \sqrt{3} & - a / ( 2 \sqrt{3} ) & - a / ( 2 \sqrt{3} ) \\ 0 & - a / 2 & - a / 2\end{matrix} ] [ \begin{matrix}{F}_{res \_ z 1} \\ {F}_{res \_ z 2} \\ {F}_{res \_ z 3}\end{matrix} ] , \qquad ( 3 )$$

where F_{res_z1} is the residual force applied at contact position z1, where F_{res_z2} is the residual force applied at contact position z2, where F_{res_z3} is the residual force applied at contact position z3, and where a is the distance from the center of each contact position to the center of the other two contact positions (in this example, a is the length of the sides of the equilateral triangle that has vertexes at contact positions z1, z2, and z3). Thus, the total residual force F_{res_z} that the out-of-plane actuators 1333 apply to the bonding-head chuck holder 1339 is the sum or net of the individual residual forces applied by the out-of-plane actuators 1333.

By controlling the out-of-plane actuators 1333, the control device 150 can control the net moment of force Mₓ around the x axis and the net moment of force M_{y} around the y axis that are produced by the forces that the out-of-plane actuators 1333 apply to the bonding-head chuck holder 1339 (and thus to bonding-head chiplet chuck 1331).

Each in-plane position sensor 1338 detects the distance from the in-plane position sensor 1338 to a respective area on a side surface 202 of the bonding-head chuck holder 1339. The control device 150 can use the in-plane position sensors 1338 to detect an in-plane rotation (a rotation around the z axis) of the bonding-head chuck holder 1339 (and the bonding-head chiplet chuck 1331).

When aligning a chiplet 22 to a bonding site 291 on the product substrate 29, the goals may be to make the tip-tilt of the chiplet 22 match the tip-tilt of the surface of the bonding site 291 on the product substrate 29 and to superposition the chiplet 22 over the bonding site 291 such that that the chiplet set of interconnect contacts and the substrate set of interconnect contacts are aligned with each other along the z axis (such that each chiplet interconnect contact and the corresponding substrate interconnect contact have the same coordinates in the x-y plane). Because it is very important that the chiplet set of interconnect contacts and the substrate set of interconnect contacts are aligned with each other, and because the chiplet set of interconnect contacts and the substrate set of interconnect contacts may be very small, when bonding a chiplet 22 to the product substrate 29, the goal may be an alignment error that is very small. For example, in some embodiments the goal is an alignment error that is less than 50-100 nm. Also for example, in some embodiments, each of the metallic pads on the chiplets 22 and on the product substrate 29 has a radius that is 1 μm to 2 μm, and the goal is to align the metallic pads on the chiplets 22 and on the product substrate 29 with a <50 nm alignment accuracy.

Also, when bonding a chiplet 22 to a bonding site 291 on the product substrate 29, one goal is to make a chiplet 22 conform to the bonding site 291. To accomplish this goal, the tip-tilt of the chiplet 22 is adjusted to match the tip-tilt of the surface of the bonding site 291. To adjust the tip-tilt of the chiplet 22, the control device 150 controls one or more of the out-of-plane actuators 1333 to adjust (e.g., increase, decrease) its applied force to adjust the tip-tilt orientation of the bonding head chuck holder 1339. The control device 150, over time, can adjust the applied force to follow a desired increasing force trajectory, which may include adjusting the forces by increasing or decreasing (for example to compensate for overshooting) the forces based on a feedback loop and a proportional-integral-derivative (PID) controller. The desired increasing force trajectory (a specified force trajectory) may be composed of desired residual forces (specified residual forces) supplied by the out-of-plane actuators 1333, over time, in the z-axis direction.

However, unobserved alignment errors may prevent these goals from being accomplished. Examples of unobserved alignment errors may include chiplet-thickness variations (chiplet tapers), chiplet shape changes (e.g., due to chucking uncertainty), and errors in tip-tilt measurements of the product substrate 29 or the bonding-head chiplet chuck 1331. For example, a chiplet 22 may have a width of 0.5-30 mm and a thickness of 50-800 μm and a 10-500 microradian tilt, or a chiplet 22 may have a width of 0.5-30 mm and a thickness of 50-800 μm and opposite sides that have a thickness variation of 1-10 μm.

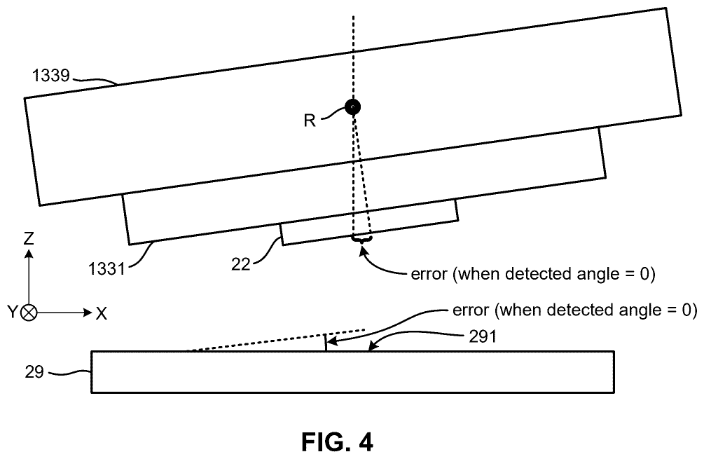

Also for example, FIG. 4 illustrates an example of an unobserved alignment error. In FIG. 4, the detected tip-tilt angle of the bonding-head chiplet chuck 1331, which is relative to the x-y plane, is zero degrees. And the bonding site 291 does not have a tip-tilt. However, the bonding-head chiplet chuck 1331 has tip-tilt angle that is greater than zero. But the tip-tilt angle is too small to be detected (for purposes of illustration, the tip-tilt angle in FIG. 4 is exaggerated), and is thus unobserved. Also, because of the distance between the center of rotation R of the bonding-head chuck holder 1339 and the chiplet 22, the error at the chiplet 22 is magnified (which is an example of an Abbe error). Thus, there are an undetected alignment error and an undetected tip-tilt error between the chiplet 22 and the bonding site 291 on the product substrate 29 to which the chiplet 22 has been aligned.

Because of the tip-tilt error between the tip-tilt of the chiplet 22 and the tip-tilt of the bonding site 291, the chiplet 22 may not properly conform to the bonding site 291 during the bonding of the chiplet 22 to the bonding site 291. And the tip-tilt error between the chiplet 22 and the bonding site 291 may also cause a mis-alignment during the bonding of the chiplet 22 to the bonding site 291.

The control device 150 may control the bonding head 133 to eliminate or reduce alignment errors and to conform a chiplet 22 to a bonding site 291 when bonding the chiplet 22 to a substrate 29.

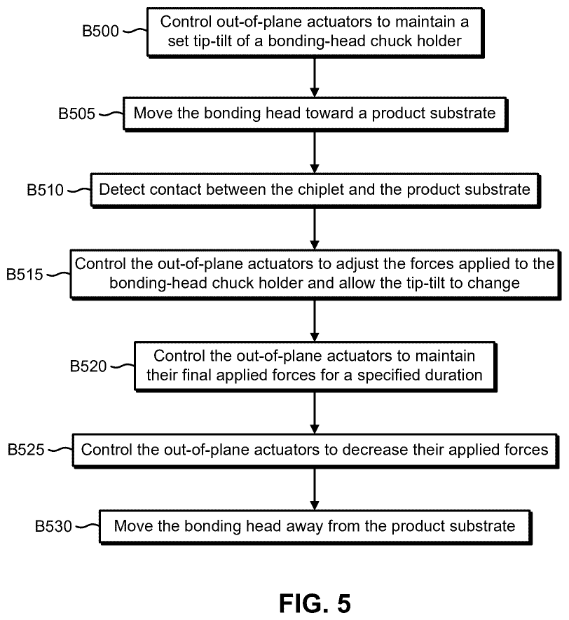

FIG. 5 illustrates an example embodiment of an operational flow for bonding a chiplet to a substrate. Although this operational flow and the other operational flows that are described herein are each presented in a certain respective order, some embodiments of these operational flows perform at least some of the operations in different orders than the presented orders. Examples of different orders include concurrent, parallel, overlapping, reordered, simultaneous, incremental, and interleaved orders. Also, some embodiments of these operational flows include operations (e.g., blocks) from more than one of the operational flows that are described herein. Thus, some embodiments of the operational flows may omit blocks, add blocks (e.g., include blocks from other operational flows that are described herein), change the order of the blocks, combine blocks, or divide blocks into more blocks relative to the example embodiments of the operational flows that are described herein.

This operational flow and the other operational flows that are described herein are performed by a bonding system 100, and one or more control devices 150 can control the bonding system 100 to perform the operations that are described in the operational flows.

In FIG. 5, in blocks B500-B510, a control device 150 operates in a z-tip-tilt-control mode (e.g., a z-tip-tilt-control state). In the z-tip-tilt-control mode (i.e., during z-tip-tilt control), the control device 150 controls the bonding system to maintain the set tip-tilt of the bonding-head chiplet chuck 1331 while bringing the bonding head 133 (particularly a chiplet 22 that is held by the bonding head 133) into contact with a product substrate 29.

In block B500, a control device 150 controls the out-of-plane actuators 1333 of a bonding head 133 to move a bonding-head chuck holder 1339 and a bonding-head chiplet chuck 1331 that holds a chiplet 22 to a set tip-tilt and maintain the set tip-tilt. The set tip-tilt may match the tip-tilt of a bonding site 291 on the product substrate 29.

Next, in block B505, the control device 150 controls the bonding system 100 to move the bonding head 133 toward the product substrate 29, which is held by a product chuck 134, by controlling one or both the bonding head 133 and the product chuck 134 to move. In block B505, the set tip-tilt is maintained, and the chiplet 22 has been aligned to the bonding site 291. Thus, the distance along the z axis between the chiplet 22 and the bonding site 291 decreases while the bonding system 100 holds the set tip-tilt of the chiplet 22.

For example, aligning the chiplet 22 to the bonding site 291 may include the following: obtaining a tip-tilt measurement of the chiplet 22 (e.g., using a gap sensor); measuring the tip-tilt of the bonding site 291 on the product substrate 29; adjusting the tip-tilt of the chiplet 22 to the same tip-tilt as the bonding site 291; correcting in-plane errors caused by the tip-tilt adjustment (these errors (Abbe errors) may include errors induced by the offset between the axis of rotation of the chiplet 22 and the surface of the chiplet 22 (the chiplet-substrate interface)); measuring the in-plane alignment (x, y, and e alignment) of the chiplet 22 with the bonding site 291; and correcting any in-plane errors of the chiplet 22 and retaking alignment measurements of the chiplet 22 to confirm the correction. And one or more of the x-axis position, the y-axis position, the z-axis position, the in-plane rotation (θ), the tip, and the tilt the chiplet 22 may be reset to zero at this time.

In block B510, the control device 150 detects contact between the chiplet 22 and the product substrate 29. In some embodiments, the current or voltage that is supplied to an out-of-plane actuator 1333 indicates the applied force that the out-of-plane actuator 1333 applies to the bonding-head chuck holder 1339. And, in some embodiments, the control device 150 detects the contact based on a change in the respective current or voltage that is supplied to one or more of the out-of-plane actuators 1333. The respective current or voltage that is supplied to an out-of-plane actuator 1333 is measured by a respective electrical-property sensor 159.

In some embodiments, the current or voltage that is supplied to an out-of-plane actuator 1333 controls the force that is applied by the out-of-plane actuator 1333 (e.g., the applied force is proportional to the supplied current or voltage). Thus, in some embodiments, the supplied current Iₐₚₚ can be described by the following:

$${I}_{app} = {I}_{elastic} + {I}_{res} , \qquad ( 4 )$$

where I_{elastic} is the current that is supplied to the out-of-plane actuator 1333, at the set tip-tilt and z-axis position, to overcome the opposing elastic forces exerted by the flexures (which may include out-of-plane guiding flexures 1334, in-plane guiding flexures 1337, out-of-plane decoupling flexures 1341, or in-plane decoupling flexures 1342) connected to the bonding-head chuck holder 1339 to maintain the desired z-axis position and tip-tilt, and where Iᵣₑₛ is the residual current that is supplied to the out-of-plane actuator 1333 (which is supplied to generate the residual force Fᵣₑₛ). And the supplied current Iₐₚₚ can be detected by a respective electrical-property sensor 159. Although this example and some of the following examples refer to the currents that are supplied to the out-of-plane actuators 1333, in some embodiments the out-of-plane actuators 1333 are controlled by the supplied voltage. Thus, supplied voltage may be substituted for supplied current in such embodiments.

Before the chiplet 22 contacts the product substrate 29, the entire applied force Fₐₚₚ, or almost the entire applied force Fₐₚₚ, that is applied by an out-of-plane actuator 1333 is the elastic force F_{elastic}, because that is the force required to overcome the opposing forces applied by the flexures connected to the bonding-head chuck holder 1339 (these flexures may include out-of-plane guiding flexures 1334, out-of-plane decoupling flexures 1341, in-plane guiding flexures 1337, or in-plane decoupling flexures 1342) and hold the bonding-head chuck holder 1339 at the set z-tip-tilt. In this condition (when Fₐₚₚ=F_{elastic}), as described by equation (1), the residual force Fᵣₑₛ IS zero or nearly zero when the bonding head 133 is moving at a constant velocity or is at rest. The elastic force F_{elastic} may be estimated based on a measured position of the bonding-head chiplet chuck 1331 and a calibration table.

Also, in this condition Iₐₚₚ=I_{elastic}, and thus, as described by equation (5), the residual current Iᵣₑₛ is zero or nearly zero.

$${I}_{res} = {I}_{app} - {I}_{elastic} . \qquad ( 5 )$$

In some embodiments, the control device 150 sends instructions to supply currents Iₐₚₚ (or voltages) to each of the out-of-plane actuators 1333 to move the bonding-head chuck holder 1339 along a desired initial motion trajectory so that the chiplet 22 arrives close to the bonding site 291 along a motion trajectory just above the bonding site 291, taking the elastic currents I_{elastic} (or elastic voltages) into account. As the chiplet 22 approaches the bonding site 291, the bonding-head chuck holder 1339 may be moving at a small but constant velocity in the z-axis direction.

However, when the chiplet 22 is in contact with the product substrate 29 while the bonding system 100 moves the chiplet 22 toward the product substrate 29, and if the tip-tilt of the chiplet 22 does not match the tip-tilt of the bonding site on the product substrate 29, then the contact between the chiplet 22 and the product substrate 29 will exert a force moment around one or both of the x and y axes that, if unopposed, will change the tip-tilt of the chiplet 22. Thus, one or more of the out-of-plane position sensors 1335 will detect a change in the tip-tilt, and one or more of the out-of-plane actuators 1333 will need to adjust its applied force Fₐₚₚ to maintain the tip-tilt. Consequently, the control device 150 will need to adjust the actuator current Iₐₚₚ that is supplied to one or more of the out-of-plane actuators 1333 to maintain the tip-tilt. And, because the current I_{elastic} that is supplied to an out-of-plane actuator 1333 to overcome the opposing forces applied by the flexures (out-of-plane guiding flexures 1334, out-of-plane decoupling flexures 1341, in-plane guiding flexures 1337, in-plane decoupling flexures 1342) at the set tip-tilt does not change, the residual current Iᵣₑₛ that is supplied to the out-of-plane actuator 1333 changes. Accordingly, the control device 150 may detect the contact between the chiplet 22 and the product substrate 29 by detecting the change in the residual current Iᵣₑₛ that is supplied to at least one out-of-plane actuator 1333. For example, the control device 150 may detect contact between the chiplet 22 and the product substrate 29 by detecting an increase in the residual current Iᵣₑₛ that is supplied to at least one out-of-plane actuator 1333 that exceeds a threshold or by detecting that the combination of residual currents Iᵣₑₛ that are supplied to two or more out-of-plane actuators 1333 exceeds a predetermined threshold. And an exemplary combination of residual force or residual currents could be obtained using equation (3) above to determine the effective z-axis force, the force moment Mₓ around the x axis, and the force moment M_{y} around the y axis. And when one or more of these quantities exceed a predetermined threshold, then contact may be detected.

And the control device 150 may detect contact between the chiplet 22 and the product substrate 29 by detecting an increase in the residual force Fᵣₑₛ that at least one out-of-plane actuator 1333 applies to the bonding-head chuck holder 1339. For example, the control device 150 may calculate the residual force Fᵣₑₛ that an out-of-plane actuator 1333 applies to the bonding-head chuck holder 1339 based on the residual current Iᵣₑₛ that is supplied to the out-of-plane actuator 1333, for example as described by Fᵣₑₛ=Iᵣₑₛ*k, where k is the force constant of the out-of-plane actuator 1333. And the control device 150 may detect contact between the chiplet 22 and the product substrate 29 by detecting a change in a slope of a supplied-current-versus-tip-tilt curve (supplied-current-versus-displacement curve) or of a force-versus-tip-tilt curve. The control device 150 may include a feedback type proportional integral differential (PID) controller that uses information from the out-of-plane position sensors 1335, a model of the I_{etastic} as function of z-axis position, and a desired motion trajectory. And, instead of detecting contact, the control device 150 may detect when the chiplet 22 and the product substrate 29 are in close proximity (e.g., within 10 μm).

Once contact between the chiplet 22 and the product substrate 29 has been detected, the flow proceeds to block B515.

In block B515, the control device 150 changes to a force-control mode (e.g., force-control state), such as a force-moment-control mode (e.g., force-moment-control state) from the z-tip-tilt-control mode. Force control is performed in the force-control mode. And, when in the force-control mode, the control device 150 enables a change in the z-tip-tilt of the bonding-head chuck holder 1339. Also, the control device 150 progressively or incrementally adjusts (e.g., increases, decreases) the respective force that is applied by each out-of-plane actuator 1333 to follow an increasing force trajectory. For example, the control device 150 may progressively or incrementally adjust the respective force that is applied by each out-of-plane actuator 1333 such that the total residual force F_{res_Z} (a total net force) follows a specified force trajectory F(t) in the z-axis direction and the force moments Mₓ and M_{y} are regulated to 0 or to a pre-defined constant setpoint. These quantities can be calculated using the residual forces Fᵣₑₛ (or residual currents Iᵣₑₛ) through each of the out-of-plane actuators 1333, for example as described by equation (3). The control device 150 may simultaneously adjust the forces that are applied by all of the out-of-plane actuators 1333, or the control device 150 may adjust the forces that are applied by the out-of-plane actuators 1333 one by one in sequence (e.g., by making incremental adjustments in a repeating sequence of out-of-plane actuators 1333), which may include regulating the force moments Mₓ and M_{y} to zero or to a specified value ε, for example as described by the following:

$$[ \begin{matrix}{F}_{res \_ z} \\ {M}_{x} \\ {M}_{y}\end{matrix} ] = [ \begin{matrix}1 & 1 & 1 \\ a / \sqrt{3} & - a / ( 2 \sqrt{3} ) & - a / ( 2 \sqrt{3} ) \\ 0 & - a / 2 & - a / 2\end{matrix} ] [ \begin{matrix}{F}_{res \_ z 1} \\ {F}_{res \_ z 2} \\ {F}_{res \_ z 3}\end{matrix} ] ; \qquad ( 6 )$$

$${F}_{res \_ z} \to F ( t ) ; {M}_{x} \to 0 or ε ; and {M}_{y} \to 0 or ε ,$$

where F_{res_z1} is the residual force applied at contact position z1, where F_{res_z2} is the residual force applied at contact position z2, where F_{res_z3} is the residual force applied at contact position z3, where F_{res_z} is the total residual force, where F(t) is a specified force trajectory, and where a is the distance from the center of each contact position to the center of the other two contact positions. Because a force moment may be positive and may be negative, the specified value ε may be a magnitude.

For example, in some embodiments, after adjusting the residual forces that three out-of-plane actuators 1333 apply to the bonding-head chuck holder 1339, the total residual force F_{res_z}(t) that the three out-of-plane actuators 1333 apply to the bonding-head chuck holder 1339 in the z-axis direction and the force moments Mₓ(t) and M_{y}(t) can be described by the following:

$${F}_{res \_ z} ( t ) = \sum {f}_{j} ( t ) ; \qquad ( 7 )$$

$${M}_{x} ( t ) = 0 or ε ; and$$

$${M}_{y} ( t ) = 0 or ε ,$$

$$where$$

$${f}_{a} ( t ) = {f}_{1} + {k}_{a} * {r}_{a} * Δ ( t ) ,$$

$${f}_{b} ( t ) = {f}_{2} + {k}_{b} * {r}_{b} * Δ ( t ) , and$$

$${f}_{c} ( t ) = {f}_{3} + {k}_{c} * {r}_{c} * Δ ( t ) ;$$

where ε is a specified value; where f₁, f₂, and f₃ are the initial residual forces applied by the three out-of-plane actuators 1333 (e.g., the residual forces applied during z-tip-tilt-control mode before the change to the force-control mode); where kₐ, k_{b}, and k_{c} are the force constants of three out-of-plane actuators 1333 (e.g., Fᵣₑₛ=Iᵣₑₛ*kₐ); where rₐ, r_{b}, and r_{c} are the geometry parameters (e.g., position vectors) that indicate the planar distances between the contact positions of the out-of-plane actuators 1333 on the bonding-head chuck holder 1339 (e.g., contact positions z1, z2, and z3 in FIG. 3B) and the center of rotation R of the bonding-head chuck holder 1339; and where Δ(t) is the adjustment in the control-effort signal for the z-axis force. The center of rotation R is the point at which the two axes of rotation pass through each other (intersect). In some embodiments, for example the embodiment shown in FIG. 3B, r₁, r₂, and r₃ are equal (e.g., r₁=r₂=r₃=⅓). The total residual force F_{res_z}(t) and the force moments Mₓ(t) and M_{y}(t) can be calculated according to equation (3) using the residual forces (or residual currents) of the out-of-plane actuators 1333.

Furthermore, in some embodiments, the total residual force F_{res_z}(t) that three out-of-plane actuators 1333 apply to the bonding-head chuck holder 1339 in the z-axis direction after adjusting their supplied currents can be described by the following:

$${F}_{res \_ z} ( t ) = \sum {k}_{j} {i}_{j} {r}_{j} ( t ) , \qquad ( 8 )$$

$$where$$

$${i}_{a} ( t ) = {i}_{1} + {r}_{a} Δ ( t ) ,$$

$${i}_{b} ( t ) = {i}_{2} + {r}_{b} Δ ( t ) , and$$

$${i}_{c} ( t ) = {i}_{3} + {r}_{c} Δ ( t ) ;$$

where i₁, i₂, and i₃ are the initial residual currents supplied to the three out-of-plane actuators 1333 (e.g., the residual currents supplied during z-tip-tilt control before the change to current control); where kₐ, k_{b}, and k_{c} are the force constants of three out-of-plane actuators 1333; where rₐ, r_{b}, and r_{c} are the geometry parameters that indicate the distances between the contact positions of the out-of-plane actuators 1333 on the bonding-head chuck holder 1339 and the center of rotation R of the bonding-head chuck holder 1339; and where Δ(t) is the adjustment in the control-effort signal of F_{z} (e.g., the supplied current). Thus, Δ(t) may be described as the correction amount.

When adjusting the respective forces that are applied by, or the currents that are supplied to, all of the out-of-plane actuators 1333, the control device 150 may maintain the ratio of the forces that are applied by, or the currents that are supplied to, the out-of-plane actuators 1333 at the same ratio of the forces that were applied, or the currents that were supplied, in block B505, during the tip-tilt-control mode. Thus, for example, if 2:1:1 is the ratio of the forces that are applied by, or the currents that are supplied to, three out-of-plane actuators 1333 before their forces are adjusted, then 2:1:1 may be the ratio of the forces that are applied by, or the currents that are supplied to, the three out-of-plane actuators 1333 after their forces are adjusted. Accordingly, after the respective force that each out-of-plane actuators 1333 applies to the chiplet 22 has been adjusted, a relative amount of a total force, that the out-of-plane actuators 1333 apply to the chiplet chuck, that is applied by each out-of-plane actuator 1333 is maintained.

And the control device 150 may adjust the forces that are applied by, or the currents that are supplied to, the out-of-plane actuators 1333 according to other techniques. For example, the control device 150 may increase the applied forces or supplied currents such that each out-of-plane actuator 1333 has the same amount of increase.

As the forces that are applied by the out-of-plane actuators 1333 are adjusted, for example to achieve a specified force trajectory or specified force moments, the tip-tilt of the bonding-head chuck holder 1339 may change, and the change may correct any unobserved tip-tilt errors between the bonding-head chuck holder 1339 and the bonding site 291 of the product substrate 29. The areas of the chiplet 22 that are in contact with the bonding site 291 on the product substrate 29 are subjected to a force that opposes the forces that are applied by the out-of-plane actuators 1333. However, the areas of the chiplet 22 that are not in contact with the bonding site 291 on the product substrate 29 are not subjected to a force that opposes the forces that are applied by the out-of-plane actuators 1333. Thus, because the control device 150 no longer maintains the set tip-tilt of the bonding-head chuck holder 1339 (i.e., the tip-tilt may change), the areas of the chiplet 22 that are not in contact with the bonding site 291 on the product substrate 29 move toward the bonding site 291 until the chiplet 22 contacts the bonding site 291, and consequently the tip-tilt of the bonding-head chuck holder 1339 changes. This change in the tip-tilt of the bonding-head chuck holder 1339 can correct any unobserved tip-tilt errors between the chiplet 22 and the bonding site 291 on the product substrate 29. Also, this conforms the chiplet 22 to the surface of the bonding site 291.

Next, in block B520, the control device 150 controls the out-of-plane actuators 1333 to maintain their final applied forces for a specified duration.

Then, in block B525, the control device 150 controls the out-of-plane actuators 1333 to decrease the forces that they apply to the bonding-head chuck holder 1339, which may include stopping the applied forces. For example, the control device 150 may control the out-of-plane actuators 1333 to decrease the forces that they apply to the bonding-head chuck holder 1339 until the forces are zero.

Finally, in block B530, the control device 150 controls the bonding system 100 to move the bonding head 133 away from the product substrate 29.

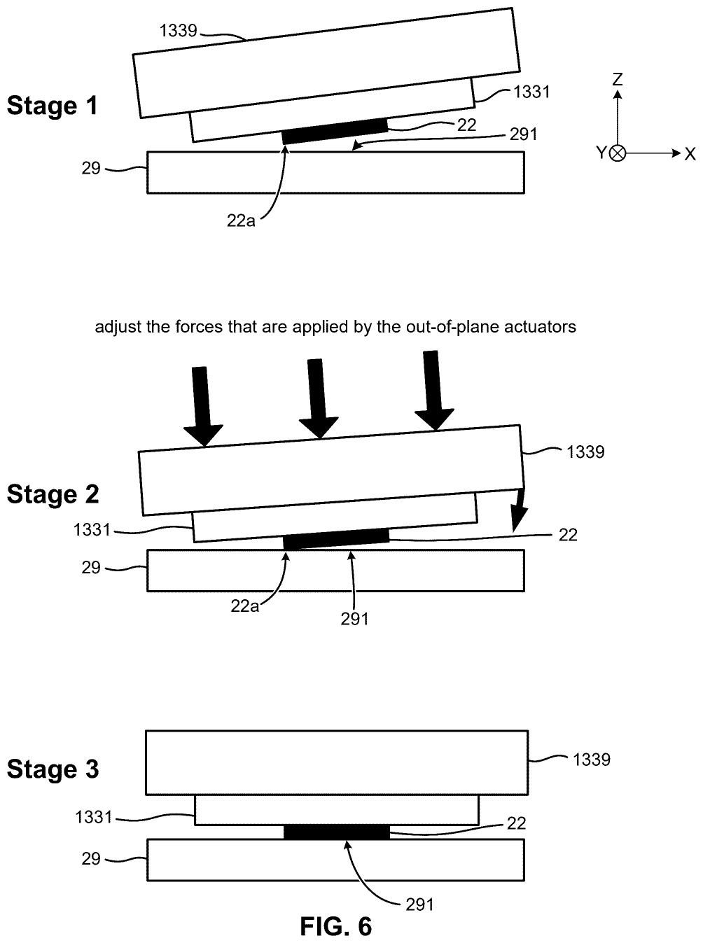

FIG. 6 illustrates an example of a chiplet being brought into contact with a substrate. In Stage 1, which corresponds to blocks B500 and B505 in FIG. 5, a chiplet 22 is moved toward a product substrate 29 while a set tip-tilt is maintained. The chiplet 22 has an unobserved tip-tilt angle, relative to the bonding site 291 on the product substrate 29, that is greater than zero.

In Stage 2, the portion 22a of the chiplet 22 that, due to the tip-tilt, is closest to the bonding site 291 on the product substrate 29 is in contact with the bonding site 291. The control device 150 detects the contact (B510), and changes to force-control mode. For example, in some embodiments, (i) one or more of the out-of-plane position sensors 1335 detect a change in the tip-tilt that is caused by the contact between the portion 22a and the bonding site 291 and by the movement of the chiplet 22 toward the bonding site 291, (ii) to maintain the tip-tilt, the control device 150 adjusts the actuator current Iₐₚₚ that is supplied to one or more of the out-of-plane actuators 1333, and (iii) the control device 150 detects the contact between the chiplet 22 and the product substrate 29 by detecting the change in the actuator current Iₐₚₚ (particularly the residual current Iᵣₑₛ component of the actuator current Iₐₚₚ) that is supplied to the one or more of the out-of-plane actuators 1333.

In force-control mode, the control device 150 enables a change in the tip-tilt, and adjusts the forces that are applied by the out-of-plane actuators 133 (B515), for example to follow a specified total force trajectory or regulate the moments of force to zero. This causes the tip-tilt of the chiplet 22 to change and moves the rest of the chiplet 22 toward the bonding site 291.

In Stage 3, the chiplet 22 is in full contact with the product substrate 29, and the chiplet 22 conforms to the bonding site 291. And the control device 150 maintains the applied forces for a specified duration (B520).

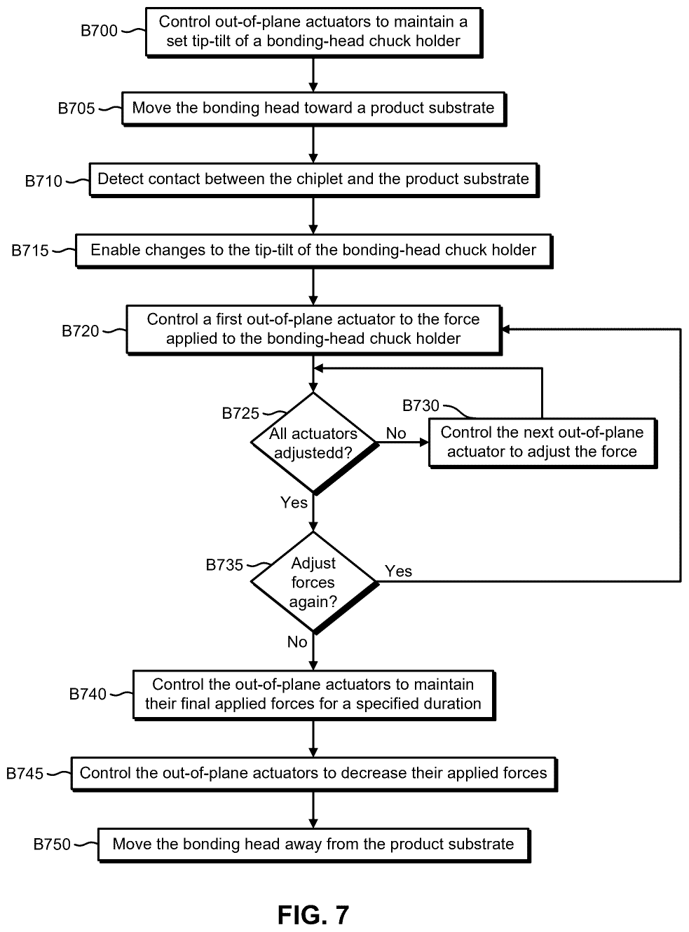

FIG. 7 illustrates an example embodiment of an operational flow for bonding a chiplet to a substrate. In blocks B700-B710, a control device 150 operates in a z-tip-tilt-control mode. In block B700, the control device 150 controls the out-of-plane actuators 1333 of a bonding head 133 to maintain a set tip-tilt of a bonding-head chuck holder 1339 and a bonding-head chiplet chuck 1331 that holds a chiplet 22. Next, in block B705, the control device 150 controls the bonding system 100 to move the bonding head 133 toward a product substrate 29, which is held by a product chuck 134, by controlling one or both the bonding head 133 and the product chuck 134 to move. In block B705, the set tip-tilt is maintained, and the chiplet 22 has been aligned to the bonding site 291. Thus, the distance along the z axis between the chiplet 22 and the bonding site 291 decreases while the bonding system 100 holds the set tip-tilt of the chiplet 22.

Then, in block B710, the control device 150 detects contact between the chiplet 22 and the product substrate 29. Then, in block B715, the control device 150 changes to a force-control mode, and changes to the tip-tilt of the bonding-head chuck holder 1339 are enabled in the force-control mode.

Next, in block B720, the control device 150 controls a first out-of-plane actuator 1333 to adjust the force it applies to the bonding-head chuck holder 1339 to follow an increasing specified force trajectory. Depending on the situation, following an increasing specified force trajectory may include reducing the force (for example to compensate for overshooting) applied by an out-of-plane actuator 1333. The flow then moves to block B725, where the control device 150 determines whether the respective forces applied by all of the out-of-plane actuators 1333 have been adjusted. If the respective forces have not all been adjusted (block B725=No), then the flow moves to block B730, where the control device 150 controls the next out-of-plane actuator 1333 to adjust the force it applies to the bonding-head chuck holder 1339. And the flow then returns to block B725. The adjustments in the applied forces may be equal across all of the out-of-plane actuators 1333, and the adjustments in the applied forces may be different among at least some of the out-of-plane actuators 1333. Also, the forces may be adjusted such that the ratios of the applied forces before and after all of the applied forces have been adjusted are the same. And the forces may be adjusted such that a specified force trajectory or specified moments of force are achieved.

If the respective forces have all been adjusted (block B725=Yes), then the flow proceeds to block B735.

In block B735, the control device 150 determines whether to again adjust the forces applied by the out-of-plane actuators 1333. For example, the control device 150 may determine whether the respective forces applied by the out-of-plane actuators 1333 have reached respective specified values or whether a specific number of iterations of blocks B720-B730 have been performed. If the control device 150 determines to again adjust the forces applied by the out-of-plane actuators 1333 (B735=Yes), then the flow returns to block B720. Thus, the control device 150 may repeat blocks B720-B730. By repeating blocks B720-B730, the control device 150 repeatedly and incrementally adjusts the forces applied by the out-of-plane actuators 1333, one by one. The adjustment in each iteration of blocks B720-B730 may be the same as, or different from, the other iterations of blocks B720-B730.

If the control device 150 determines not to again adjust the forces applied by the out-of-plane actuators 1333 (B735=No), then the flow moves to block B740.

In block B740, the control device 150 controls the out-of-plane actuators 1333 to maintain their final applied forces for a specified duration. Next, in block B745, the control device 150 controls the out-of-plane actuators 1333 to decrease the forces that they apply to the bonding-head chuck holder 1339, which may include stopping the applied forces. And, in block B750, the control device 150 controls the bonding system 100 to move the bonding head 133 away from the product substrate 29.

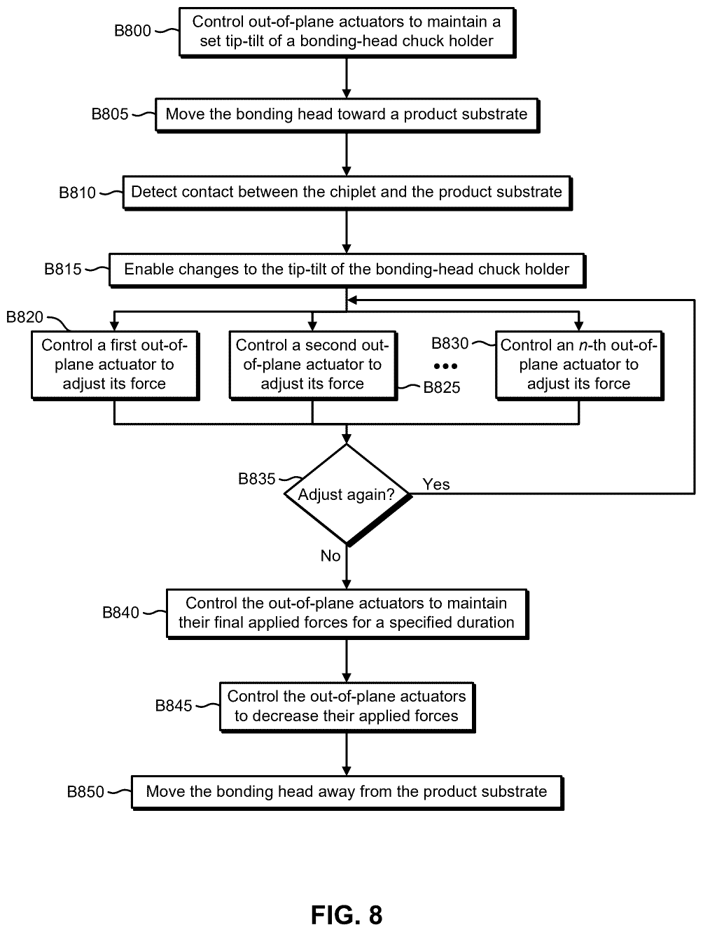

FIG. 8 illustrates an example embodiment of an operational flow for bonding a chiplet to a substrate. In blocks B800-B810, a control device 150 operates in a z-tip-tilt-control mode. In block B800, the control device 150 controls the out-of-plane actuators 1333 of a bonding head 133 to maintain a set tip-tilt of a bonding-head chuck holder 1339 and a bonding-head chiplet chuck 1331 that holds a chiplet 22. Next, in block B805, the control device 150 controls the bonding system 100 to move the bonding head 133 toward a product substrate 29, which is held by a product chuck 134, by controlling one or both the bonding head 133 and the product chuck 134 to move. In block B805, the set tip-tilt is maintained, and the chiplet 22 has been aligned to the bonding site 291. Thus, the distance along the z axis between the chiplet 22 and the bonding site 291 decreases while the bonding system 100 holds the set tip-tilt of the chiplet 22.

Then, in block B810, the control device 150 detects contact between the chiplet 22 and the product substrate 29. Following, in block B815, the control device 150 changes to a force-control mode, and, in the force-control mode, changes to the tip-tilt of the bonding-head chuck holder 1339 are enabled. The flow then splits into n flows, where n is the number of out-of-plane actuators 1333. The n flows may be performed simultaneously.

The first flow of the n flows proceeds to block B820, where the control device 150 controls a first out-of-plane actuator 1333 to adjust the force it applies to the bonding-head chuck holder 1339. The second flow of the n flows proceeds to block B825, where the control device 150 controls a second out-of-plane actuator 1333 to adjust the force it applies to the bonding-head chuck holder 1339. The n-th of the n flows flow proceeds to block B830, where the control device 150 controls an n-th out-of-plane actuator 1333 to adjust the force it applies to the bonding-head chuck holder 1339.

The n flows all proceed to block B835, where the control device 150 determines whether to again adjusts the forces applied by the out-of-plane actuators 1333. For example, the control device 150 may determine whether the respective forces applied by the out-of-plane actuators 1333 have reached respective specified values or whether a specific number of iterations of blocks B820-B830 have been performed. If the control device 150 determines to again adjusts the forces applied by the out-of-plane actuators 1333 (B835=Yes), then the flow again splits into the n flows, which return to blocks B820-B830. Thus, the control device 150 may repeat blocks B820-B830. By repeating blocks B820-B830, the control device 150 repeatedly and simultaneously adjusts the forces applied by the out-of-plane actuators 1333 in increments. The adjustment in each iteration of blocks B820-B830 may be the same as, or different from, the other iterations of blocks B820-B830.

If the control device 150 determines not to adjust the forces applied by the out-of-plane actuators 1333 (B835=No), then the flow moves to block B840.

In block B840, the control device 150 controls the out-of-plane actuators 1333 to maintain their final applied forces for a specified duration. Next, in block B845, the control device 150 controls the out-of-plane actuators 1333 to decrease the forces that they apply to the bonding-head chuck holder 1339, which may include stopping the applied forces. And, in block B850, the control device 150 controls the bonding system 100 to move the bonding head 133 away from the product substrate 29.

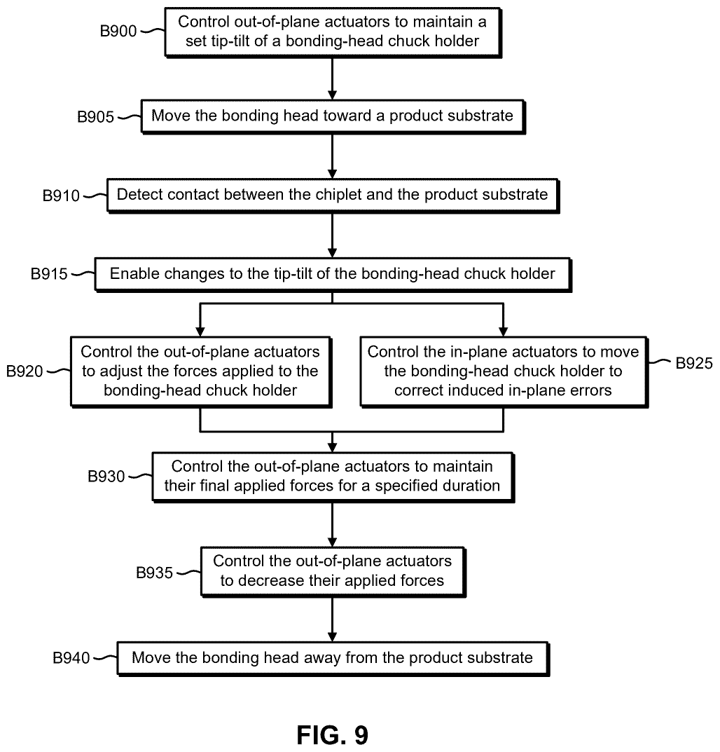

FIG. 9 illustrates an example embodiment of an operational flow for bonding a chiplet to a substrate. In blocks B900-B910, a control device 150 operates in a z-tip-tilt-control mode. In block B900, the control device 150 controls the out-of-plane actuators 1333 of a bonding head 133 to maintain a set tip-tilt of a bonding-head chuck holder 1339 and a bonding-head chiplet chuck 1331 that holds a chiplet 22. Next, in block B905, the control device 150 controls the bonding system 100 to move the bonding head 133 toward a product substrate 29, which is held by a product chuck 134, by controlling one or both the bonding head 133 and the product chuck 134 to move. In block B905, the set tip-tilt is maintained, and the chiplet 22 has been aligned to the bonding site 291. Thus, the distance along the z axis between the chiplet 22 and the bonding site 291 decreases while the bonding system 100 holds the set tip-tilt of the chiplet 22.

Then, in block B910, the control device 150 detects contact between the chiplet 22 and the product substrate 29.

Following, in block B915, the control device 150 changes to a force-control mode, and, in the force-control mode, changes to the tip-tilt of the bonding-head chuck holder 1339 are enabled.

The flow then splits into two flows, which may be performed simultaneously.

The first flow proceeds to block B920, where the control device 150 controls the out-of-plane actuators 1333 to adjust the respective forces they apply to the bonding-head chuck holder 1339. Also, block B920 may include the operations that are described in blocks B720-B735 in FIG. 7 or in blocks B820-B835 in FIG. 8. The first flow then moves to block B930.

The second flow advances to block B925, where the control device 150 controls the in-plane actuators 1336 to move the bonding-head chuck holder 1339 to correct any induced in-plane errors. The control in block B925 may be based on a distance between the chiplet 22 and an axis of rotation of the chiplet 22.

For example, in-plane motions may be caused by unobserved errors, such as Abbe errors. For example, the bonding-head chuck holder 1339 may have six degrees of freedom, and the control device 150 can obtain measurements from the out-of-plane position sensors 1335 and the in-plane position sensors 1338. Using the measurements, the control device 150 can detect (e.g., calculate) in-plane induced motions (e.g., due to translation on the x axis, translation on the y axis, or rotation around the z axis) of the chiplet 22, and the control device 150 can use the measurements to correct the in-plane Abbe errors induced as the tip-tilt of the bonding-head chuck holder 1339 changes while the chiplet 22 is made to conform to the surface of the bonding site 291. And some embodiments of the control device 150 use the currents or voltages that are supplied to the out-of-plane actuators 1333 to detect the in-plane induced motions of the chiplet 22 in addition to, or in alternative to, the measurements from the out-of-plane position sensors 1335 and the in-plane position sensors 1338.

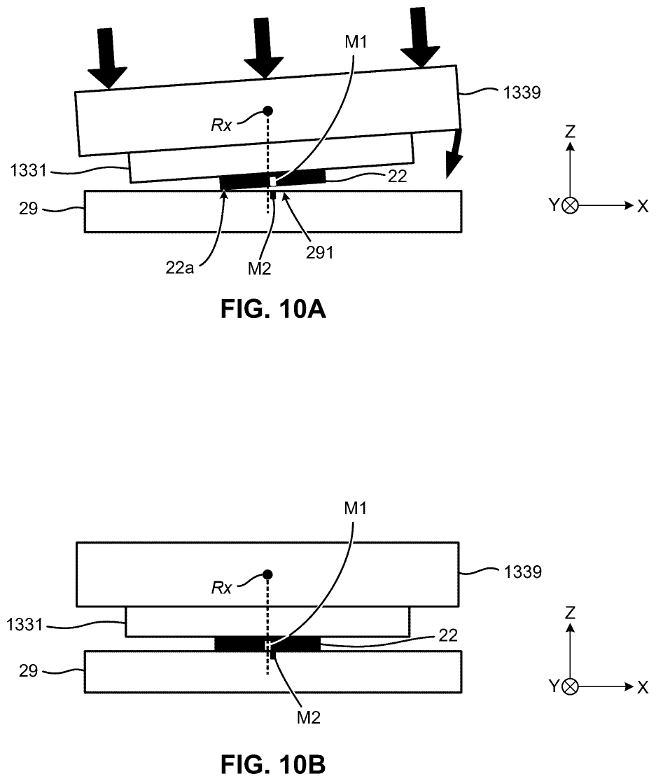

For example, FIG. 10A illustrates an example of a chiplet being brought into contact with a product substrate. The portion 22a of the chiplet 22 that, due to the tip-tilt of the bonding-head chuck holder 1339, is closest to the bonding site 291 on the product substrate 29 is in contact with the product substrate 29. Also, in the x-y plane, alignment mark M1 on the chiplet 22 is aligned with alignment mark M2 on the product substrate. And, along the x axis, the axis of rotation Rx of the bonding-head chuck holder 1339 is not aligned with both alignment mark M1 and alignment mark M2. Furthermore, the bonding system 100 does not detect the tip-tilt of the bonding-head chuck holder 1339. Thus, the bonding system 100 detects that the axis of rotation Rx of the bonding-head chuck holder 1339 is aligned with alignment mark M1, and the tip-tilt of the bonding-head chuck holder 1339 is an unobserved error.

As the forces that are applied by the out-of-plane actuators 1333 adjust and the tip-tilt of the bonding-head chuck holder 1339 changes, the tip-tilt of the chiplet 22 changes to conform the chiplet 22 to the substrate 29, and the portions of the chiplet 22 that are not in contact with the product substrate 29 move toward the product substrate 29. Because the tip-tilt of the chiplet 22 changes around the axis of rotation Rx, the in-plane position (x-y position) of the chiplet 22 will change without additional changes to the in-plane position of the bonding-head chuck holder 1339. For example, FIG. 10B shows the chiplet 22 from FIG. 10A after the chiplet 22 has been brought into full contact with (conformed to) the product substrate 29. The tip-tilt of the chiplet 22 changed without any change to the in-plane position of the axis of rotation Rx. Changing the tip-tilt of the bonding-head chuck holder 1339 and the chiplet 22 changed the in-plane position of the chiplet 22. After the tip-tilt was changed, alignment mark M1 is aligned with the axis of rotation Rx, and the tip-tilt of the chiplet 22 has been corrected to match the tip-tilt of the bonding site 291. However, because the axis of rotation Rx was not aligned with alignment mark M2, alignment mark M1 is no longer aligned with alignment mark M2. Thus, the chiplet 22 is no longer aligned to the bonding site 291 on the product substrate 29.

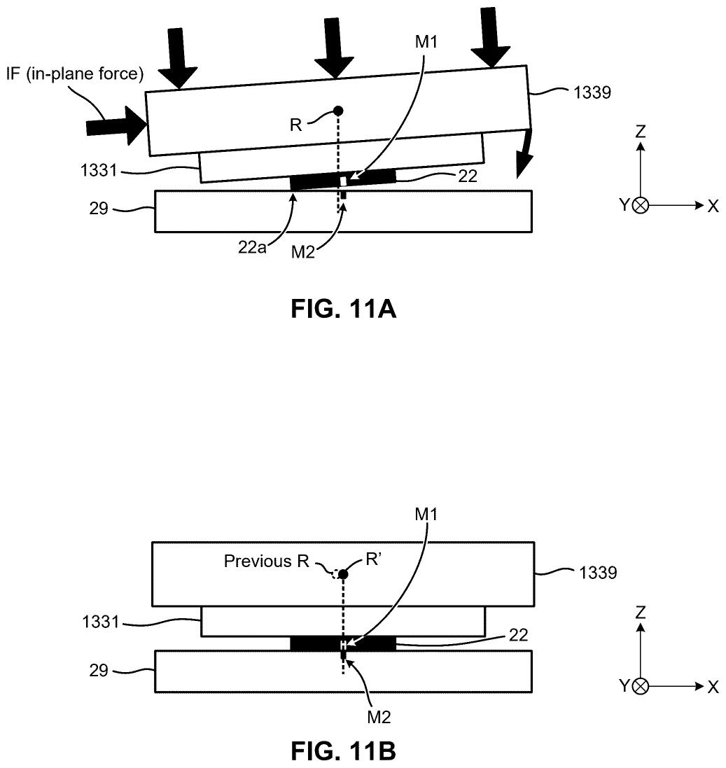

To prevent such mis-alignments, some embodiments of the bonding system 100 change the in-plane position of the bonding-head chuck holder 1339 as the tip-tilt of the bonding-head chuck holder 1339 changes to maintain the alignment of the chiplet 22 to the product substrate 29, for example to maintain the alignments of one or more points (e.g., alignment marks) on the chiplet 22 to respective points (e.g., alignment marks) on the product substrate 29. For example, FIG. 11A illustrates an example of a chiplet being brought into contact with a product substrate. FIG. 11A is similar to FIG. 10A. However, in FIG. 11A, the control device 150 controls one or more in-plane actuators 1336 to apply an in-plane force IF to the bonding-head chuck holder 1339 in the positive x-axis direction as the tip-tilt of the bonding-head chuck holder 1339 changes. Furthermore, the control device 150 controls the out-of-plane actuators 1333 and other in-plane actuators 1336 to maintain the alignment of alignment mark M1 to alignment mark M2. As shown in FIG. 11B, this maintains the in-plane alignment of alignment mark M1 and alignment mark M2 as the undetected error in the tip-tilt of the chiplet 22 is corrected and the chiplet 22 is brought into full contact with the product substrate 29. By combining the in-plane motion with tip-tilt of the bonding-head chuck holder 1339, it appears that the bonding-head chuck holder 1339 is rotating about rotation axes passing through, for example, M2, which may be collinear with R′, as shown in FIG. 11B. The in-plane position of the previous axis of rotation Rx (from FIG. 11A) is shown with a dashed line.

Accordingly, in block B925, the control device 150 can control the out-of-plane actuators 1333 and the in-plane actuators 1336 to change the in-plane position of one or more axes of rotation of the bonding-head chuck holder 1339, which are also the axes of rotation of the chiplet 22, while maintaining the in-plane position of one or more points on the chiplet 22, based on the change in the tip-tilt of the chiplet 22 and on the distance between the chiplet 22 and the axes of rotation. Also, in effect, the control device 150 can control the chiplet 22 and the bonding-head chuck holder 1339 to rotate about an arbitrary axis of rotation or point of rotation, such as a point on the bonding surface of the chiplet 22 or the substrate 29 bonding surface. For example, in FIGS. 11A-B, the axis of rotation along the y axis of the chiplet 22 and the bonding-head chuck holder 1339 may effectively be alignment mark M1 or the alignment mark M2 on the substrate 29. In an embodiment, the control device 150 can control the out-of-plane actuators 1333 and the in-plane actuators 1336 to adjust the in-plane position of the chiplet 22 to minimize an alignment error between the chiplet 22 and the substrate 29 while also regulating the moment of force to a predetermined value and moving the bonding-head chiplet chuck 1331 toward the third substrate chuck 134 without maintaining the set tip-tilt of the bonding-head chiplet chuck 1331.

From block B925, the second flow moves to block B930, where the second flow rejoins the first flow. In block B930, the control device 150 controls the out-of-plane actuators 1333 to maintain their final applied forces for a specified duration. Next, in block B935, the control device 150 controls the out-of-plane actuators 1333 to decrease the forces that they apply to the bonding-head chuck holder 1339, which may include stopping the applied forces. And, in block B940, the control device 150 controls the bonding system 100 to move the bonding head 133 away from the product substrate 29.

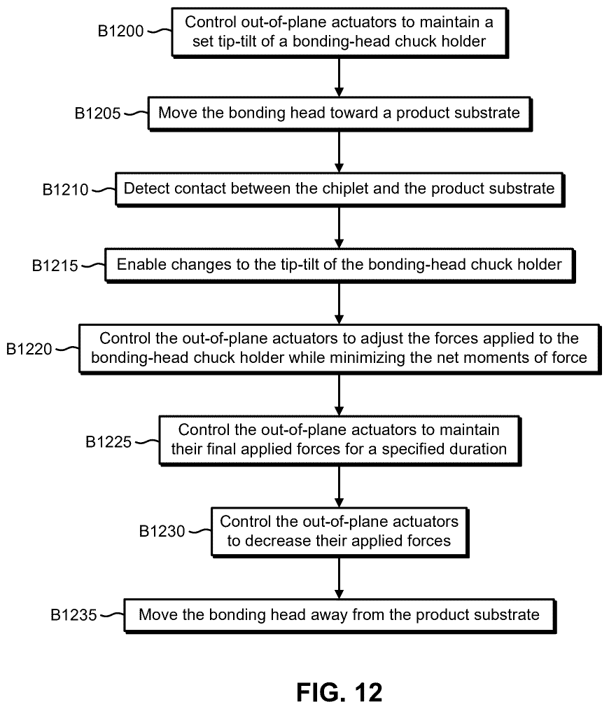

FIG. 12 illustrates an example embodiment of an operational flow for bonding a chiplet to a substrate. In blocks B1200-B1210, the control device 150 operates in a z-tip-tilt-control mode. The flow starts in block B1200, where a control device 150 controls the out-of-plane actuators 1333 of a bonding head 133 to maintain a set tip-tilt of a bonding-head chuck holder 1339 and a bonding-head chiplet chuck 1331 that holds a chiplet 22. Next, in block B1205, the control device 150 controls the bonding system 100 to move the bonding head 133 toward a product substrate 29, which is held by a product chuck 134, by controlling one or both the bonding head 133 and the product chuck 134 to move. In block B1205, the set tip-tilt is maintained, and the chiplet 22 has been aligned to the bonding site 291. Thus, the distance along the z axis between the chiplet 22 and the bonding site 291 decreases while the bonding system 100 holds the set tip-tilt of the chiplet 22.

Then, in block B1210, the control device 150 detects contact between the chiplet 22 and the product substrate 29. And, in block B1215, the control device 150 changes to a force-moment-control mode (which is an example of a force-control mode), and changes to the tip-tilt of the bonding-head chuck holder 1339 are enabled in the force-moment-control mode.

In block B1220, the control device 150 controls the out-of-plane actuators 1333 to adjust the forces that they apply to the bonding-head chuck holder 1339, for example as described in blocks B720-B735 in FIG. 7 or in blocks B820-B835 in FIG. 8. When adjusting the forces that are applied by the out-of-plane actuators 1333, the control device 150 also performs moment control, which controls the moment of force around the x axis (Mₓ) and the moment of force around the y axis (M_{y}) such that they satisfy one or more criteria (e.g., remain below a threshold (which may be a magnitude), approach a particular value). For example, the control device 150 may adjust the forces that are applied by the out-of-plane actuators 1333 such that the magnitude of the moment of force around the x axis (Mₓ) and the magnitude of the moment of force around the y axis (M_{y}) are zero, approach zero, are a finite predetermined value (e.g., if the chiplet 22 is offset from the center of the bonding-head chuck holder 1339, then the moments of force around the center of the bonding-head chuck holder center may be regulated to a finite constant), or are otherwise maintained as low as the bonding system 100 is able. Thus, in some embodiments that include three out-of-plane actuators 1333 (e.g., the embodiments shown in FIG. 3B), the applied residual forces and the moments of force can be described by the following:

$$[ \begin{matrix}{F}_{res \_ z} \to F ( t ) \\ {M}_{x} \to 0 ( or ε ) \\ {M}_{y} \to 0 ( or ε )\end{matrix} ] = [ \begin{matrix}1 & 1 & 1 \\ a / \sqrt{3} & - a / ( 2 \sqrt{3} ) & - a / ( 2 \sqrt{3} ) \\ 0 & - a / 2 & - a / 2\end{matrix} ] [ \begin{matrix}{F}_{res \_ z 1} \\ {F}_{res \_ z 2} \\ {F}_{res \_ z 3}\end{matrix} ] , \qquad ( 9 )$$

where F_{res_z1} is the residual force applied at contact position z1, where F_{res_z2} is the residual force applied at contact position z2, where F_{res_z3} is the residual force applied at contact position z3, where F_{res_z} is the total residual force, where F(t) is a force trajectory, where a is the distance from the center of each contact position to the center of the other two contact positions, where M_{y} is the net moment of force around the x axis, where M_{y} is the net moment of force around the y axis, and where ε is a specified value.

In block B1225, the control device 150 controls the out-of-plane actuators 1333 to maintain their final applied forces for a specified duration. Next, in block B1230, the control device 150 controls the out-of-plane actuators 1333 to decrease the forces that they apply to the bonding-head chuck holder 1339, which may include stopping the applied forces. And, in block B1235, the control device 150 controls the bonding system 100 to move the bonding head 133 away from the product substrate 29.

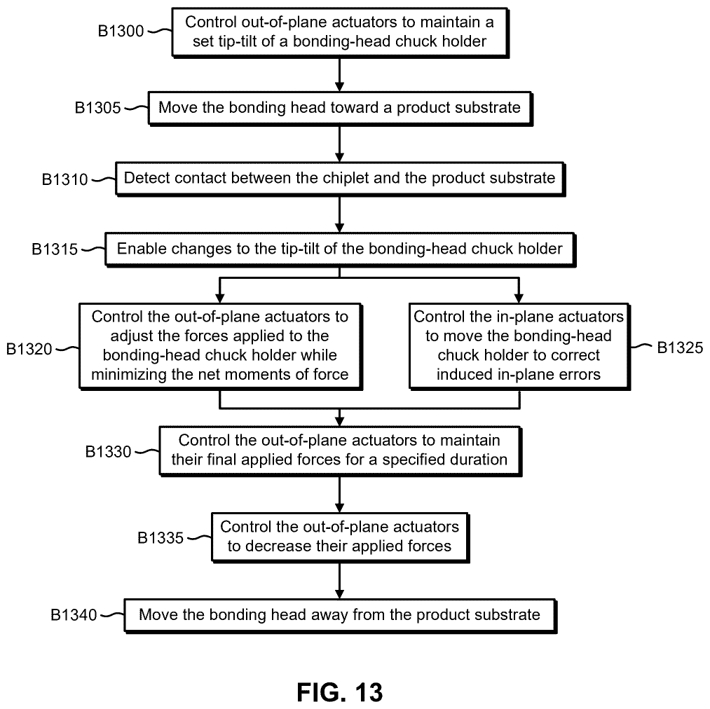

FIG. 13 illustrates an example embodiment of an operational flow for bonding a chiplet to a substrate. In blocks B1300-B1310, the control device 150 operates in a z-tip-tilt-control mode. The flow starts in block B1300, where a control device 150 controls the out-of-plane actuators 1333 of a bonding head 133 to maintain a set tip-tilt of a bonding-head chuck holder 1339 and a bonding-head chiplet chuck 1331 that holds a chiplet 22. Next, in block B1305, the control device 150 controls the bonding system 100 to move the bonding head 133 toward a product substrate 29, which is held by a product chuck 134, by controlling one or both the bonding head 133 and the product chuck 134 to move. In block B1305, the set tip-tilt is maintained, and the chiplet 22 has been aligned to the bonding site 291. Thus, the distance along the z axis between the chiplet 22 and the bonding site 291 decreases while the bonding system 100 holds the set tip-tilt of the chiplet 22.

Then, in block B1310, the control device 150 detects contact between the chiplet 22 and the product substrate 29. And, in block B1315, the control device 150 changes to a force-moment-control mode, and, in the force-moment-control mode, changes to the tip-tilt of the bonding-head chuck holder 1339 are enabled.

In block B1320, the control device 150 controls the out-of-plane actuators 1333 to adjust the forces that they apply to the bonding-head chuck holder 1339, for example as described in blocks B720-B735 in FIG. 7 or in blocks B820-B835 in FIG. 8. When adjusting the forces that are applied by the out-of-plane actuators 1333, the control device 150 also performs moment control, which controls the moment of force around the x axis (Mₓ) and the moment of force around the y axis (M_{y}) such that they satisfy one or more criteria (e.g., remain below a threshold, approach a particular value). For example, the control device 150 may adjust the forces that are applied by the out-of-plane actuators 1333 such that the moment of force around the x axis (Mₓ) and the moment of force around the y axis (M_{y}) are zero, approach zero, are a finite predetermined value, or are otherwise maintained as low as the bonding system 100 is able.

And, while performing block B1320, the control device 150 performs block B1325. In block B1325, the control device 150 controls in-plane actuators 1336 to move the bonding-head chuck holder 1339 to correct any induced in-plane errors (e.g., Abbe error), for example as described in block B925 in FIG. 9. Accordingly, the control device 150 may control the out-of-plane actuators 1333 and the in-plane actuators 1336 to change the in-plane position of the axes of rotation of the bonding-head chuck holder 1339, which are also the axes of rotation of the chiplet 22, while maintaining the in-plane position of one or more points on the chiplet 22.

In block B1330, the control device 150 controls the out-of-plane actuators 1333 to maintain their final applied forces for a specified duration. Next, in block B1335, the control device 150 controls the out-of-plane actuators 1333 to decrease the forces that they apply to the bonding-head chuck holder 1339, which may include stopping the applied forces. And, in block B1340, the control device 150 controls the bonding system 100 to move the bonding head 133 away from the product substrate 29.

In some embodiments, including the embodiments that are described herein, the control device 150 may implement the force-control mode (including the force-moment-control mode) using either feedforward control (e.g., open-loop feedforward control) or feedback control (e.g., closed-loop feedback control). In feedforward control, the magnitudes of the control variables (the applied forces, the moments of force) are used as a feedforward setpoint or trajectory. In feedback control, the currents or voltages that are supplied to the out-of-plane actuators 1333 are measured to estimate the real-time force and moments of force, which are then used as the feedback signal to control the total force and moments of force.

FIG. 14 illustrates the x-axis, y-axis, z-axis, θ, ψ, and φ directions of a bonding-head chuck holder. As used herein, “in-plane” refers to a direction in the x-y plane, and “out-of-plane” refers to a direction on the z axis. Also, θ indicates a rotation around the z axis (an “in-plane” rotation). ψ, the tip, refers to a rotation around the y axis. And φ, the tilt, refers to a rotation around the x axis.

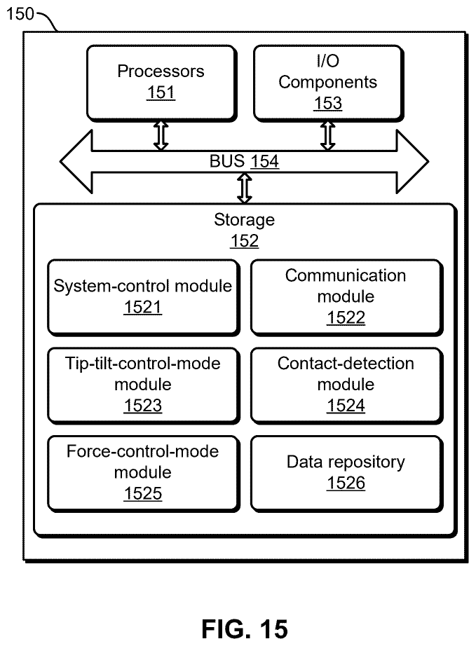

FIG. 15 is a schematic illustration of an example embodiment of a control device 150. The control device 150 includes one or more processors 151, one or more computer-readable storage media 152, one or more I/O components 153, and a bus 154.

The control device 150 additionally includes a system-control module 1521, a communication module 1522, a tip-tilt-control-mode module 1523, a contact-detection module 1524, and a force-control-mode module 1525. As used herein, a module includes logic, computer-readable data, or computer-executable instructions. In the embodiment shown in FIG. 15, the modules are implemented in software (e.g., Assembly, C, C++, C#, Java, JavaScript, BASIC, Perl, Visual Basic, Python, PHP). However, in some embodiments, the modules are implemented in hardware (e.g., customized circuitry) or, alternatively, a combination of software and hardware. When the modules are implemented, at least in part, in software, then the software can be stored in the one or more computer-readable storage media 152. Also, in some embodiments, the control device 150 includes additional or fewer modules, the modules are combined into fewer modules, or the modules are divided into more modules. And a module may use (e.g., call) other modules. Also, the control device 150 includes a data repository 1526, which stores information, such as models (e.g., tables, matrixes) that indicate the forces (e.g., elastic forces) that are applied by out-of-plane guiding flexures 1334 (and, in some embodiments, in-plane guiding flexures 1337) over the entire motion space of bonding-head chuck holders 1339.

The system-control module 1521 includes instructions that cause the applicable components (e.g., the one or more processors 151, the storage 152, the I/O components 153) of the control device 150 to communicate with and to control the other members of a bonding system 100. For example, some embodiments of the system-control module 1521 include instructions that cause the applicable components of the control device 150 to control the bonding system 100 to perform at least some of the operations that are described in blocks B525-B530 in FIG. 5, in blocks B745-B750 in FIG. 7, in blocks B845-B850 in FIG. 8, in blocks B935-B940 in FIG. 9, in blocks B1230-B1235 in FIG. 12; and in blocks B1335-B1340 in FIG. 13. And the applicable components operating according to the system-control module 1521 realize an example of a system-control unit.

The communication module 1522 includes instructions that cause the applicable components (e.g., the one or more processors 151, the storage 152, the I/O components 153) of the control device 150 to communicate with one or more other devices, such as other computing devices (e.g., the networked computer 160 in FIG. 1) and input or output devices (e.g., the display 155 and the keyboard 156 in FIG. 1). And the applicable components operating according to the communication module 1522 realize an example of a communication unit.

The tip-tilt-control-mode module 1523 includes instructions that cause the applicable components (e.g., the one or more processors 151, the storage 152, the I/O components 153) of the control device 150 to control the components of the bonding system 100 to move a bonding-head chiplet chuck 1331 (which can hold a chiplet 22) and a product chuck 134 (which can hold a product substrate 29) toward each other while maintaining a set tip-tilt and in-plane position of the bonding-head chiplet chuck 1331 relative to the product chuck 134. For example, some embodiments of the tip-tilt-control-mode module 1523 include instructions that cause the applicable components of the control device 150 to control the bonding system 100 to perform at least some of the operations that are described in blocks B500-B505 in FIG. 5, in blocks B700-B705 in FIG. 7, in blocks B800-B805 in FIG. 8, in blocks B900-B905 in FIG. 9, in blocks B1200-B1205 in FIG. 12, and in blocks B1300-B1305 in FIG. 13. And the applicable components operating according to the tip-tilt-control-mode module 1523 realize an example of a tip-tilt-control-mode unit.

The contact-detection module 1524 includes instructions that cause the applicable components (e.g., the one or more processors 151, the storage 152, the I/O components 153) of the control device 150 to control the components of the bonding system 100 to detect contact between a chiplet 22 and a product substrate 29 and to change a control mode of the control device 150 to change from a z-tip-tilt-control mode to a force-control mode (e.g., a force-moment-control mode). For example, some embodiments of the contact-detection module 1524 include instructions that cause the applicable components of the control device 150 to control the bonding system 100 to perform at least some of the operations that are described in block B510 in FIG. 5, in blocks B710-B715 in FIG. 7, in blocks B810-B815 in FIG. 8, in blocks B910-B915 in FIG. 9, in blocks B1210-B1215 in FIG. 12, and in blocks B1310-B1315 in FIG. 13. And the applicable components operating according to the contact-detection module 1524 realize an example of a contact-detection unit.

The force-control-mode module 1525 includes instructions that cause the applicable components (e.g., the one or more processors 151, the storage 152, the I/O components 153) of the control device 150 to control the components of the bonding system 100 to adjust the forces that out-of-plane actuators 1333 apply to a bonding-head chiplet chuck 1331 (which can hold a chiplet 22) without maintaining a set tip-tilt and of the bonding-head chiplet chuck 1331 relative to the product chuck 134. The forces may be adjusted according to various criteria, including maintaining a specific of the ratio of the forces that are applied by the out-of-plane actuators 1333 or minimizing the moments of force around one or both of the x and y axes. Also, the instructions may cause the applicable components of the control device 150 to control the components of the bonding system 100 to move the bonding-head chiplet chuck 1331 to correct any induced in-plane errors. For example, some embodiments of the force-control-mode module 1525 include instructions that cause the applicable components of the control device 150 to control the bonding system 100 to perform at least some of the operations that are described in blocks B515-B520 in FIG. 5, in blocks B720-B740 in FIG. 7, in blocks B820-B840 in FIG. 8, in blocks B920-B930 in FIG. 9, in blocks B1220-B1225 in FIG. 12, and in blocks B1320-B1330 in FIG. 13. And the applicable components operating according to the force-control-mode module 1525 realize an example of a force-control-mode unit.

This method is applicable to other methods of device processing, such as nanoimprint lithography, inkjet adaptive planarization, and immersion lithography.

At least some of the above-described devices, systems, and methods can be implemented, at least in part, by providing one or more computer-readable media that contain computer-executable instructions for realizing the above-described operations to one or more computing devices that are configured to read and execute the computer-executable instructions. The systems or devices perform the operations of the above-described embodiments when executing the computer-executable instructions. Also, an operating system on the one or more systems or devices may implement at least some of the operations of the above-described embodiments.

Furthermore, some embodiments use one or more functional units to implement the above-described devices, systems, and methods. The functional units may be implemented in only hardware (e.g., customized circuitry) or in a combination of software and hardware (e.g., a microprocessor that executes software).

In the description, specific details are set forth in order to provide a thorough understanding of the embodiments disclosed. However, well-known methods, procedures, components and circuits may not have been described in detail in order to avoid unnecessarily lengthening the present disclosure.

Also, if a member (e.g., element, part, component) is referred herein as being “on,” “against,” “connected to,” or “coupled to” another member, then the member can be directly on, against, connected or coupled to the other member, but intervening members may also be present between the member and the other member. In contrast, if a member is referred to as being “directly on,” “directly against,” “directly connected to,” or “directly coupled to” another member, then there are no intervening members present between the member and the other member.

Furthermore, the terms “comprising,” “having,” “includes,” “including,” and “containing” are to be construed as open-ended terms unless otherwise noted. Accordingly, these terms, when used in the present specification, specify the presence of described features, integers, steps, operations, elements, materials, or members, but do not preclude the presence or addition of one or more other features, integers, steps, operations, elements, materials, or members that are not explicitly described.

1. A method of bonding a chiplet held by a chiplet chuck to a substrate with a bonding head, the method comprising:
controlling a plurality of actuators to move a chiplet chuck holding a chiplet toward a substrate while maintaining a set tip-tilt of the chiplet chuck;
detecting contact of the chiplet with the substrate based on a change of a force applied to the chiplet chuck by at least one actuator of the plurality of actuators while maintaining the set tip-tilt of the chiplet chuck; and,
after detecting the contact of the chiplet with the substrate, controlling the plurality of actuators to move the chiplet chuck toward the substrate without maintaining the set tip-tilt of the chiplet chuck and adjusting a respective force that each actuator of the plurality of actuators applies to the chiplet chuck such that a predetermined condition is satisfied.

2. The method of claim 1, wherein the predetermined condition is that a specified force trajectory is maintained.

3. The method of claim 1, wherein adjusting the respective force that each actuator of the plurality of actuators applies to the chiplet chuck includes:
repeatedly adjusting the respective force that each actuator of the plurality of actuators applies to the chiplet chuck.

4. The method of claim 1,
wherein each actuator of the plurality of actuators applies a respective moment of force to the chiplet chuck, wherein the respective moment of force is based on the respective force that is applied to the chiplet chuck by the actuator and on a position where the chiplet chuck receives the force from the actuator, and
wherein the predetermined condition is that, after the respective force that each actuator of the plurality of actuators applies to the chiplet chuck has been adjusted, a magnitude of a sum of the respective moments of force is below a threshold.

5. The method of claim 4, wherein the sum of the respective moments of force is zero.

6. The method of claim 1, further comprising:
while controlling the plurality of actuators to move the chiplet chuck toward the substrate without maintaining the set tip-tilt of the chiplet chuck, maintaining an in-plane position of at least one point on the chiplet while changing a position of an axis of rotation of the chiplet.

7. The method of claim 1, wherein adjusting the respective force that each actuator of the plurality of actuators applies to the chiplet chuck includes adjusting a respective current or a respective voltage that is supplied to each actuator of the plurality of actuators.

8. The method of claim 1, wherein detecting contact of the chiplet with the substrate based on the change of the force applied to the chiplet chuck by at least one actuator of the plurality of actuators while maintaining the set tip-tilt of the chiplet chuck includes:
detecting an increase in a current or a voltage that is supplied to the at least one actuator in order to maintain the set tip-tilt of the chiplet chuck.

9. The method of claim 1, further comprising:
manufacturing an article by processing the substrate.

10. A system comprising:
a frame;
a chiplet chuck that is configured to hold a chiplet;
a plurality of actuators that are coupled to the frame and the chiplet chuck;
one or more processors; and
one or more memories,
wherein the one or more processors and the one or more memories are configured to:
control a plurality of actuators to move the chiplet chuck toward a substrate while maintaining a set tip-tilt of the chiplet chuck;
detect contact of a chiplet held by the chiplet chuck with the substrate based on a change of a force applied to the chiplet chuck by at least one actuator of the plurality of actuators while maintaining the set tip-tilt of the chiplet chuck; and
after detecting the contact of the chiplet held by the chiplet chuck with the substrate,
adjust a respective force that each actuator of the plurality of actuators applies to the chiplet chuck such that a predetermined condition is satisfied and
control the plurality of actuators to move the chiplet chuck toward the substrate without maintaining the set tip-tilt of the chiplet chuck.

11. The system of claim 10, wherein the predetermined condition is that, as the forces that the plurality of actuators are applying to the chiplet chuck are adjusted by a force adjustment amount, a relative amount of the force adjustment amount that the plurality of actuators are applying to the chiplet chuck that is applied by each actuator of the plurality of actuators is maintained.

12. The system of claim 10, wherein to adjust the respective force that each actuator of the plurality of actuators applies to the chiplet chuck, the one or more processors and the one or more memories are further configured to:
repeatedly adjust the respective force that each actuator of the plurality of actuators applies to the chiplet chuck.

13. The system of claim 10, wherein each actuator of the plurality of actuators applies a respective moment of force to the chiplet chuck, wherein the respective moment of force is based on the respective force that is applied to the chiplet chuck by the actuator and on a position on the chiplet chuck where the chiplet chuck receives the respective force from the actuator, and
wherein the predetermined condition is that, after the respective force that each actuator of the plurality of actuators applies to the chiplet chuck has been adjusted, a magnitude of a sum of the respective moments of force is maintained below a threshold.

14. The system of claim 13, wherein the sum of the respective moments of force is zero.

15. The system of claim 10, wherein the one or more processors and the one or more memories are further configured to:
while controlling the plurality of actuators to move the chiplet chuck toward the substrate without maintaining the set tip-tilt of the chiplet chuck, maintain an in-plane position of at least one point on the chiplet while changing a position of an axis of rotation of the chiplet.

16. The system of claim 10, further comprising:
a plurality of electrical-property sensors, wherein the plurality of electrical-property sensors measure a respective current or a respective voltage that is supplied to each actuator of the plurality of actuators,
wherein to detect contact of the chiplet held by the chiplet chuck with the substrate based on the change of the force applied to the chiplet chuck by at least one actuator of the plurality of actuators while maintaining the set tip-tilt of the chiplet chuck, the one or more processors and the one or more memories are configured to:
detect an increase in the respective current or the respective voltage that is supplied to the at least one actuator in order to maintain the set tip-tilt of the chiplet chuck.

17. The system of claim 10, further comprising:
a plurality of flexures that are coupled to the frame and the chiplet chuck,
wherein the respective force that each actuator of the plurality of actuators applies to the chiplet chuck opposes forces that the plurality of flexures apply to the chiplet chuck, and
wherein to detect contact of the chiplet held by the chiplet chuck with the substrate based on the change of the force applied to the chiplet chuck by at least one actuator of the plurality of actuators while maintaining the set tip-tilt of the chiplet chuck, the one or more processors and the one or more memories are configured to:
determine whether the force applied to the chiplet chuck by at least one actuator of the plurality of actuators is greater than a force that the at least one actuator applies to the chiplet chuck to maintain the set tip-tilt of the chiplet chuck, wherein the force that the at least one actuator applies to the chiplet chuck to maintain the set tip-tilt of the chiplet chuck is based on the forces that the plurality of flexures apply to the chiplet chuck at the set tip-tilt of the chiplet chuck.

18. A device comprising:
one or more communication interfaces that are configured to communicate with a plurality of actuators and a chiplet chuck that is configured to hold a chiplet;
one or more processors; and
one or more memories,
wherein the one or more processors and the one or more memories are configured to:
control the plurality of actuators to move the chiplet chuck toward a substrate while maintaining a set tip-tilt of the chiplet chuck;
detect contact of a chiplet held by the chiplet chuck with the substrate based on a change of a force applied to the chiplet chuck by at least one actuator of the plurality of actuators while maintaining the set tip-tilt of the chiplet chuck; and
after detecting the contact of the chiplet held by the chiplet chuck with the substrate,
adjust a respective force that each actuator of the plurality of actuators applies to the chiplet chuck such that a predetermined condition is satisfied and
control the plurality of actuators to move the chiplet chuck toward the substrate without maintaining the set tip-tilt of the chiplet chuck.

19. The device of claim 18, wherein the predetermined condition is that a specified force trajectory is maintained.

20. The device of claim 18, wherein the one or more processors and the one or more memories are further configured to:
while controlling the plurality of actuators to move the chiplet chuck toward the substrate without maintaining the set tip-tilt of the chiplet chuck, maintain an in-plane position of at least one point on the chiplet while changing a position of an axis of rotation of the chiplet.
